(19) United States
(12) Patent Application Publication
(10) Pub. No.: US 2012/0192922 A1
(43) Pub. Date: Aug. 2, 2012

(54) SOLAR COLLECTOR

(75) Inventor: Christopher Leslie Waring, Mt Keira (AU)

(73) Assignee: CONSUNTRATE PTY LTD, Mt Keira, NSW (AU)

(21) Appl. No.: 13/502,224

(22) PCT Filed: Oct. 18, 2010
(86) PCT No.: PCT/AU10/01376

§ 371 Date: Apr. 16, 2012

(30) Foreign Application Priority Data
Oct. 16, 2009 (AU) 2009905048

(51) Int. Cl. H01L 31/058; G02B 5/10; F24J 2/04; F24J 2/38; H01L 31/0232; H01L 31/052

(52) U.S. Cl. 136/248; 136/259; 136/246; 126/646; 126/600; 359/853

(57) ABSTRACT

A reflector to reflect solar radiation, the reflector having a concave reflector surface, wherein the surface curves about a first axis and a second axis, the second axis being in a plane generally normal to the first axis and curved about the first axis. Also disclosed is an apparatus for collection and utilization of solar energy including at least one of the reflectors, and at least one photovoltaic cell associated with each surface and positioned relative to the associated surface so as to be positioned to receive radiation reflected by the associated surface and to convert the radiation to electrical energy. The apparatus further includes heat a conversion mechanism for converting excess solar radiation energy incident thereon to heat energy.

### TECHNICAL FIELD

The present invention relates to solar concentrators and in particular to solar concentrators for collection of solar energy for solar power and solar heating.

The invention has been developed primarily for use as a solar concentrator for efficient collection and conversion of solar energy to electricity and/or solar hot water applications and will be described hereinafter with reference to this application. However, it will be appreciated that the invention is not limited to this particular field of use.

### BACKGROUND

Any discussion of the background art throughout the specification should in no way be considered as an admission that such background art is prior art, nor that such background art is widely known or forms part of the common general knowledge in the field.

Devices for collection and concentration of solar radiation are well known and often come in the form of a reflector with broad overall geometric forms of a linear focus trough or point focus dish. Both troughs and dish solar collectors may use a parabolic reflector which reflects solar radiation incident thereon to a focal point (dish) or with a linear focus (trough) at which location is placed a device such as a photovoltaic cell (e.g. a solar cell) for conversion of the solar radiation to electrical power. Alternatively, the solar radiation may be concentrated to a focal point where the heat from the solar radiation is used to heat a substance e.g. water for solar hot water applications.

Also known are concentrators which have a primary reflector and a secondary imaging element. In these devices the primary reflector is again either a circular or parabolic dish which directs the solar radiation incident thereon to the secondary imaging element, typically a refractive element, to finally focus the solar radiation to the photovoltaic cell.

Such dish-based solar concentrators are large and unwieldy, and are often impractical for residential installations. Also, dish shaped solar concentrators require a solar cell close to the focal point, which limits the size of the dish to approximately 500-1400 cm² when matched to commercially available 1 cm² solar cells. Each dish typically requires its own tracking system and support structure which significantly increases the cost of the power generated. Two approaches have been adopted to partially overcome these constraints: a) increase the size of the dish and obtain/develop customised solar cells at increased unit cost, or b) stack smaller dish concentrators together onto a common frame for tracking. However, circular dishes, for example, do not pack with optimal space efficiency.

Another disadvantage of dish-based solar concentrators is that the centre of gravity is often somewhere between the focal point and base of the dish. For the dish to track the sun it needs to track in two axes which is structurally most efficient at the centre of gravity thereby requiring that a section of the dish be removed to allow for the support pole. Other dish support structures and tracking systems are possible but are likely to be more expensive to construct and unwieldy by comparison.

Where solar radiation is converted into electrical power, the amount of power a solar collector can provide is proportional to the product of the concentration factor (suns) and the photovoltaic conversion efficiency of the solar cell (%). Many existing solar collectors rely on passive cooling to remove heat. However, maximisation of the concentration factor (suns) results in a temperature increase of a solar cell and causes a lowering of the cell light conversion efficiency. Therefore, the rate of heat removal from such passive systems limits the concentration factor of sunlight on the solar cell. As the design concentration factor increases to maximise power output, heat removal efficiency becomes a limitation. Another limitation to increasing concentration factor is the ability to effectively track the sun at high concentration factors. Optical distortions and tracking errors combine to limit increases in concentration factor.

Existing solar collectors for combined electrical power and hot water generation are typically designed to maximise the electrical power generation in preference to hot water generation because of the greater value of electrical power, particularly where solar generated electrical power is the subject of subsidies. The design objective for combined electrical power and hot water generation solar collectors is the same as for electrical power alone, that is, to maximise the product of the concentration factor and conversion efficiency.

The majority of domestic solar energy devices in, for example, Australia, use low efficiency (<17%) Si photovoltaic cells for electrical power generation and separate flat plate solar hot water systems. The basic system designs and efficiency have not changed significantly in 20 years and future performance gains ($/watt) for Si photovoltaic cells are likely to be through small incremental gains in manufacturing efficiency. However, to increase uptake rates of domestic solar installations for electrical power and hot water generation, their price needs to continually decrease in line with decreases in subsidies and a market willingness to pay a higher price for solar energy.

It is an object of the present invention to substantially overcome or at least ameliorate one or more of the disadvantages of the prior art, or at least to provide a useful alternative to existing solar concentrators.

### SUMMARY

According to a first aspect, there is provided a reflector to reflect solar radiation, the reflector having a reflector surface, the surface being concave, and wherein the surface curves about a first axis and a second axis, the second axis being in a plane generally normal to the first axis and curved about the first axis.

According to an arrangement of the first aspect, there is provided a reflector to reflect solar radiation, the reflector having a reflector surface, the surface being concave, and wherein the surface curves about a first axis and a second axis, the second axis being in a plane generally normal to the first axis and curved about the first axis.

The reflector may be elongated so that said second axis is a longitudinal axis with said surface in transverse cross-section having a parabolic configuration. The second axis may follow a parabolic path. The reflector may be elongated so that said second axis is a longitudinal axis, with said surface in transverse cross-section an elliptical configuration, a hyperbolic configuration or a configuration that is a segment of a circle.

The reflector surface may comprise a plurality of paraboloid formations, each formation forming a reflector, thereby to form an array of reflectors. Each of the paraboloid formations may be elongate, concave formations, wherein each of the formations curves about the first axis and a corresponding second axis, each corresponding second axis being in a plane generally normal to the first axis and curved about the first axis.

The reflector surface may comprise: a paraboloid profile about both the first and second axes. The primary reflector may comprise a first paraboloid profile about the first axis, and a second paraboloid profile about the second axis.

The reflector surface may comprise a cross-section profile with respect to either the first or second axes selected from the group of: a circular cross-section (i.e. a segment of a circle), a parabolic cross section; an elliptical cross-section; or a hyperbolic cross-section.

The reflector surface about either or both the first and second axes may deviate from a paraboloid such that the radiation reflected therefrom irradiates an area cell with a substantially uniform flux density.

According to a second aspect, there is provided an apparatus for collection and utilisation of solar energy. The apparatus may comprise at least one reflector, each reflector being according to the first aspect. The apparatus may further comprise at least one photovoltaic cell associated with each surface and positioned relative to the associated surface so as to receive radiation reflected by the associated surface and to convert the received radiation to electrical energy.

According to a arrangement of the second aspect, there is provided an apparatus for collection and utilisation of solar energy comprising: at least one reflector, each reflector being according to the first aspect; at least one photovoltaic cell associated with each surface and positioned relative to the associated surface so as to receive radiation reflected by the associated surface and to convert the received radiation to electrical energy.

Each surface may be configured and is positioned relative its associated said cell so that radiation reflected from each surface irradiates a receiving area of the cell with a substantially uniform flex density.

Each reflector may be a primary reflector. The apparatus may include at least one secondary reflector operatively associated with an associated one of the primary reflectors. Each secondary reflector may reflect received solar radiation at the associated primary reflector.

The at least one secondary solar concentrating element may be a frustum-shaped reflector.

The apparatus may further comprise a plurality of primary reflectors, each being a primary reflector according to the first aspect, supported by the first support portion, each primary reflector comprising a concave reflector surface. The apparatus may further comprise a plurality of photovoltaic cells supported by the second support portion, each photovoltaic cell being disposed to receive radiation incident on and reflected by the reflector surface of the corresponding primary reflector.

The apparatus may further comprise a plurality of secondary reflectors according to the secondary reflectors of the first aspect, each secondary reflector operatively associated with a respective primary reflector and a corresponding photovoltaic cell.

The apparatus may further comprise two arrays of primary reflectors and respective photovoltaic cells, said arrays been fixedly attached to opposing sides of the first support portion. Each array of primary reflectors may comprise a continuous reflective sheet having a plurality of concave reflective surfaces in operative engagement with a respective photovoltaic cell.

The second support portion may comprise heat conversion means in the second support portion for converting excess solar radiation energy incident thereon to heat energy, wherein the at least one photovoltaic cell is in thermal communication with the heat conversion means for transferring excess solar radiation incident on the at least one photovoltaic cell to the heat conversion means by conductive heat transfer.

The heat conversion means may comprise a means for flowing a fluid therethrough, wherein said fluid is heated by excess solar radiation incident on the second support portion. The heat conversion means may comprise a hollow portion or duct in the second support portion and a pump for flowing a fluid through the hollow portion or duct. The fluid may be water. In use, the fluid is heated by excess solar radiation incident on the second support portion and excess solar radiation incident on the photovoltaic cell, where such excess solar radiation is converted to heat rather than electrical energy. The heat conversion means may regulate the temperature of the photovoltaic cell. At least part of the fluid from the heat conversion means may be flowed to a storage tank comprising a fluid inlet for topping up the fluid level, and a fluid outlet for removing fluid, particularly hot fluid. Where the hot fluid removed from outlet is hot water, this may be suitable for domestic or commercial use. Alternatively, where a fluid other than water is used, a heat exchanger may be placed after fluid outlet to provide hot water for domestic or commercial use. At least part of the fluid from the heat conversion means or from the storage tank may be flowed to a radiator where excess heat may be dissipated before being returned to the hollow portion or duct of the heat conversion means by the pump. The flow rate of pump may be variable and may be operated by a flow control means which includes a temperature sensor (e.g. a thermocouple) operatively disposed to measure the temperature of circulating fluid. The pump speed and thereby the flow rate of fluid through the hollow portion or duct of the heat conversion means may be dictated by the temperature of the circulating fluid measured and resultantly the temperature of the fluid exiting the heat conversion means.

According to a third aspect, there is provided an apparatus for collection and utilisation of solar energy. The apparatus may comprise first and second support portions. The at least one primary reflector may be supported by the first support portion. The reflector may including a concave reflector surface. The at least one photovoltaic cell may be supported by the second support portion, and may be positioned to receive radiation reflected by the reflector surface to convert said radiation to electrical energy. The reflective surface curves about a first axis and second axis, the second axis being in a plane generally normal to the first axis and curved about the first axis. The reflector may be as according to the first aspect.

According to an arrangement of the third aspect, there is provided an apparatus for collection and utilisation of solar energy comprising first and second support portions; at least one primary reflector supported by the first support portion, reflector including a concave reflector surface; at least one photovoltaic cell supported by the second support portion, and positioned to receive radiation reflected by the reflector surface and to convert said radiation to electrical energy; wherein the reflective surface curves about a first axis and second axis, the second axis being in a plane generally normal to the first axis and curved about the first axis.

The reflector surface may comprise a paraboloid profile about both the first and second axes. The reflector surface may comprise a cross-section profile selected from the group of: a circular cross-section (i.e. a segment of a circle), a parabolic cross section; an elliptical cross-section; or a hyperbolic cross-section. The primary reflector may comprise a compound parabolic reflector comprising a first paraboloid profile about the first axis, and a second paraboloid profile about the second axis.

The reflector surface about either or both the first and second axes may deviate from a paraboloid such that the radiation reflected therefrom irradiates a receiving area of the photovoltaic cell with a substantially uniform flux density.

The apparatus may comprise a plurality of primary reflectors, each being a primary reflector as described above, supported by the first support portion, each primary reflector comprising a concave reflector surface; and a plurality of photovoltaic cells supported by the second support portion, each photovoltaic cell being disposed to receive radiation incident, on and reflected by the reflector surface of the corresponding primary reflector.

The apparatus may further comprise at least one secondary reflector, in constant optical working engagement with a corresponding primary reflector and a corresponding photovoltaic cell, the secondary reflector adapted for receiving and redirecting solar radiation from the corresponding primary reflector on to the respective photovoltaic cell, where such radiation would otherwise have not been incident on the photovoltaic cell. The at least one secondary solar concentrating element is a frustum-shaped reflector. The apparatus may further comprise a plurality of secondary reflectors each being in constant working engagement with a respective primary reflector and a corresponding photovoltaic cell.

The apparatus may comprise two arrays of primary reflectors and respective photovoltaic cells, said arrays been fixedly attached to opposing sides of the first support portion. Each array of primary reflectors may comprise a continuous reflective sheet having a plurality of concave reflective surfaces in operative engagement with a respective photovoltaic cell. The concave reflective surfaces may each comprise a paraboloid profile about the first axis. Each paraboloid profile may comprise a paraboloid profile about an associated second axis, each second axis being in a plane generally normal to the first axis and curved about the first axis. The concave reflective surfaces may each comprise a first paraboloid profile about the first axis, and a second paraboloid profile about an associated second axis.

The second support portion may comprise heat conversion means for converting excess solar radiation energy incident thereon to heat energy. The at least one photovoltaic cell may be in thermal communication with the heat conversion means for transferring excess solar radiation incident on the at least one photovoltaic cell to the heat conversion means by conductive heat transfer. The heat conversion means may comprise a means for flowing a fluid therethrough, wherein in use said fluid is heated by excess solar radiation incident on the second support portion.

The support frame may be supported by at least one pivot rotatable in at least two directions. The apparatus may further comprise solar tracking means for moving the support frame about the pivot to adjust an elevation angle of the apparatus and a horizontal angle of the apparatus with respect to changes in the direction of incident solar radiation over a daylight period, thereby to track the sun's motion across the sky and incident solar radiation incident on the at least one primary reflector to the photovoltaic cell.

According to an alternate arrangement of the third aspect, there is provided an apparatus for collection and utilisation of solar energy. The apparatus may comprise first and second support portions. The apparatus may further comprise at least one primary reflector supported by the first support portion. The primary reflector may comprise a first axis and a second axis normal to the first axis. The primary reflector may be arcuate about both the first and second axes. The primary reflector may be adapted for focusing radiation incident thereon to a focal point or area. The apparatus may further comprise at least one photovoltaic cell supported by the second support portion. The photovoltaic cell may be positioned to receive radiation incident on the at least one primary reflector. The primary reflector may be elongate, wherein the first axis may be aligned along a longitudinal dimension of the primary reflector, and the second axis may be aligned along a transverse dimension of the primary reflector.

In a further arrangement of the third aspect, there is provided an apparatus for collection and utilisation of solar energy comprising: first and second support portions; at least one primary reflector supported by the first support portion, said primary reflector comprising a first axis and a second axis normal to the first axis, wherein the primary reflector is arcuate about both the first and second axes, and adapted for focusing radiation incident thereon to a focal point or area; at least one photovoltaic cell supported by the second support portion, said photovoltaic cell being positioned to receive radiation incident on the at least one primary reflector.

The at least one primary reflector may comprise a paraboloidal profile about either or both the first and second axes. The at least one primary reflector may be profiled about both the first and second axes to direct radiation incident thereon to the focal point or area. The directed radiation forms an image at the focal point, however, the focal point is not in general a point image, but rather an extended area image, for example imaged on to a receiving area (active area) of the photovoltaic cell. The at least one primary reflector may be a concave reflector. The at least one primary reflector may comprise: a parabolic or circular (i.e. a segment of a circle) profile along the first axis; and a parabolic or circular (i.e. a segment of a circle) profile along the second axis. The at least one primary reflector may comprise: a circular (i.e. a segment of a circle) profile along the first axis; and a circular (i.e. a segment of a circle) profile, along the second axis. The at least one primary reflector may comprise: a curved profile along the first axis which is intermediate between a circular (i.e. a segment of a circle) and a parabolic profile; and a circular along the second axis. The circular profile of any of the above arrangements may be a semi-circular or partially circular profile, wherein the semi-circular profile comprises a circular arc of about 180 degrees and a partially circular profile comprises a circular arc of less than 180 degrees, for example an arc subtending an angle of between about 5 degrees and about 180 degrees from a point. The primary reflector may be arcuate. The primary reflector may be segmented. The primary reflector may be formed from a plurality of linear segments. The primary reflector formed from a plurality of linear segments may approximate an arcuate profile, for example the plurality of linear segments may approximate a circular (i.e. a segment of a circle), parabolic, elliptical, hyperbolic, or other arcuate or curved profile. The primary reflector may be ovoid, for example semi- or quarter-ovoid along either the first or the second axes. The primary reflector may be semi- or quarter-spherical along either the first or the second axes. The primary reflector may comprise a reflective film. The primary reflector may have an inner surface and an outer surface, the inner surface being reflective. The reflective film may be disposed on the inner surface of the primary reflector. The reflective film may be a weatherproof Aluminium sheet (e.g. MIRO-SUN 90 weatherproof, 0.3 mm thick). The reflective film may be removable and replaceable.

The apparatus of the third aspect may comprise a plurality of primary reflectors supported by the first support portion. Each primary reflector may be curved in both the first and second axis. Each primary reflector may be adapted for focusing radiation incident thereon to a respective focal point or area. The apparatus may further comprise a plurality of photovoltaic cells supported by the second support portion. Each photovoltaic cell may be disposed at or proximal to the focal point or area of a corresponding reflector for receiving radiation incident on and reflected by the corresponding reflector, and may be positioned to receive the reflected radiation.

In particular arrangements, each of the one or more primary reflector(s) may be profiled to provide a distributed flux density of reflected radiation across a receiving area of the corresponding photovoltaic cell.

The first support portion may be elongate and the plurality of primary reflectors may be configured in at least one linear array along the elongate first support portion. The second support portion may be elongate and the plurality of photovoltaic cells may be disposed in at least one linear array along the elongate second support portion.

Each of the plurality of primary reflectors may be maintained in constant optical working engagement with a corresponding photovoltaic cell. The first support portion may be fixedly attached to the second support portion to form a support frame. The support frame may be rigid to facilitate the plurality of primary reflectors being maintained in constant optical working engagement with a corresponding photovoltaic cell. The cross-section of the support frame may approximate an arch.

The plurality of primary reflectors may be arranged in the form of a continuous corrugated sheet. Each primary reflector may be defined between the adjacent apexes of the corrugated sheet. Adjacent primary reflectors may be separate from and spaced apart from one another.

The apparatus may further comprise at least one secondary reflector or refractor, in constant optical working engagement with a corresponding primary reflector and a corresponding photovoltaic cell. The at least one secondary reflector or refractor may direct incident radiation to the corresponding photovoltaic cell. Where the apparatus comprises a plurality of primary reflectors and a plurality of corresponding photovoltaic cells, the apparatus may further comprise a plurality of secondary reflectors or refractors each associated with a corresponding primary reflector and corresponding photovoltaic cell. The at least one secondary reflector may be frustum-shaped. The at least one secondary reflector may comprise a mirrored surface. The at least one secondary reflector may comprise a reflective film. The reflectance of the secondary reflector may be between about 80%, and about 100%, for example may be about 80%, 85%, 90%, 95% or about 100% reflective. The at least one secondary reflector may have an inner surface and an outer surface, the inner surface being reflective. The reflective film may be disposed on the inner surface of the secondary reflector. The reflective film or mirrored surface may be a weatherproof Aluminium sheet (e.g. MIRO-SUN 90 weatherproof, 0.3 mm thick). The at least one secondary reflector(s) may be frustum-shaped. The at least one secondary reflector or refractor may be a frustum. The frustum may have an inner and outer surface, the inner surface being reflective. The reflective film may be disposed on the inner surface of the frustum. The frustum may be disposed adjacent to its corresponding photovoltaic cell.

The apparatus of any of the second to sixth aspects may further comprise an electrical conversion means operatively coupled with the photovoltaic cell for conversion of direct current electrical power generated in the photovoltaic cell to alternating current electrical power.

The apparatus of any of the second to sixth aspects may further comprise a heat conversion means comprised in the second support portion for converting excess solar radiation energy incident thereon to heat energy, wherein the photovoltaic cell is in thermal communication with the inner support portion for transferring excess solar radiation incident on the photovoltaic cell to the heat conversion means by conductive heat transfer.

The heat conversion means may comprise a hollow portion or duct and a pump for flowing a fluid through the hollow portion or duct, wherein said fluid is heated by excess solar radiation incident on the inner support portion and excess solar radiation incident on the photovoltaic cell.

According to a seventh aspect there is provided an apparatus for collection and utilisation of solar energy. The apparatus may comprise a support frame comprising first and second support portions, wherein the first and second support portions are separated and fixedly interconnected. The apparatus may further comprise at least one primary solar concentrating element fixedly attached to the first support portion. The apparatus may further comprise at least one respective photovoltaic cell fixedly attached to the second support portion, the photovoltaic cell adapted to receive solar radiation and convert said radiation to electrical energy. The primary solar concentrating element may be adapted to receive incoming solar radiation and direct the solar radiation to the respective photovoltaic cell.

According to an arrangement of the seventh aspect there is provided an apparatus for collection and utilisation of solar energy comprising: a support frame comprising first and second support portions, wherein the first and second support portions are separated and fixedly interconnected; at least one primary solar concentrating element fixedly attached to the first support portion; and at least one respective photovoltaic cell fixedly attached to the second support portion, the photovoltaic cell adapted to receive solar radiation and convert the radiation to electrical energy, wherein the primary solar concentrating element is adapted to receive incoming solar radiation and direct the solar radiation to the respective photovoltaic cell.

In one or more arrangements of the seventh aspect, the apparatus may comprise any one or more of the following features in any suitable combination.

The support frame may be adapted to maintain a constant optical working relationship between the at least one primary solar concentrating element and the respective photovoltaic cell. The first and second support portions may be elongate. The cross-section of the support frame may approximate an arch.

In a further arrangement of the seventh aspect, the apparatus may further comprise a plurality of like primary solar concentrating elements fixedly attached to and arrayed along the elongate first support portion. In this arrangement, the apparatus may further comprise a plurality of respective photovoltaic cells fixedly attached to and arrayed along the second support portion. In this arrangement, each of the plurality of primary solar concentrating elements may be maintained by the support frame in constant optical working relationship with a respective photovoltaic cell.

The apparatus may further comprise two arrays of primary solar concentrating elements and respective photovoltaic cells, such arrays being fixedly attached to opposing sides of the first support portion. The plurality of primary solar concentrating elements may be adapted to be fixedly attached to at least one adjacent like primary solar concentrating element. The primary solar concentrating elements may be configured such that a tie rod may be coupled to a plurality of primary concentrating elements in an array to secure that array of primary solar concentrating elements. The tie rod may reinforce the array to which it is secured. Each primary concentrating element may have a passage located on its outer surface through which the tie rod can pass. The passages on the outer surfaces of adjacent primary concentrating elements may be aligned so that a tie rod can pass through the passages and secure the adjacent primary concentrating elements. Once the tie rod has passed through the passages a securing lug may be placed on either end of the tie rod to prevent it from slipping out of the passages. Each array of primary reflectors comprises a continuous reflective sheet having a plurality of concave reflective surfaces in operative engagement with a respective photovoltaic cell

In the arrangements comprising at least one array of primary solar concentrating elements, each of the primary solar concentrating elements in the array may be separated from adjacent like solar concentrating elements by a distance of between about 5 to 40 cm. In other arrangements, each of the solar concentrating elements in the array may be separated from adjacent like solar concentrating elements by a distance of about 10, 15, 20, 25, 30 or 35 cm. There may also be a gap between the primary solar concentrating element(s) fixedly attached to the first support portion to allow drainage of any rain and dust. There may also be a narrow gutter running longitudinally along the primary solar concentrating element(s) to allow drainage of any rain and dust.

In further arrangements of the seventh aspect, the at least one primary solar concentrating element(s) of the apparatus may take the form of at least one primary reflector(s) of the first aspect.

According to an eighth aspect, there is provided an apparatus according to any of the second to seventh aspects for utilisation of solar energy, wherein the second support portion further comprises a heat conversion means for converting excess solar radiation energy incident thereon to heat energy. At least one photovoltaic cell may also be in thermal communication with the heat conversion means for transferring excess solar radiation incident on the at least one photovoltaic cell to the heat conversion means by conductive heat transfer.

The heat conversion means may comprise a means for flowing a fluid there through, wherein in use said fluid is heated by excess solar radiation incident on the second support portion. The heat conversion means may comprise a hollow aluminium extrusion. In particular arrangements, the fluid may be water and the heat conversion means may be adapted to provide water at a temperature of greater than 50 degrees Celsius. The heat conversion means may be adapted to provide water at a temperature of between about 50 degrees Celsius and about 70 degrees Celsius. The water may be directed to a storage tank. In other arrangements, the first support portion may comprise a radiator to receive fluid exiting the heat conversion means where excess heat is dissipated before being returned to the heat conversion means. In further arrangements, the support frame may comprise a radiator to receive fluid exiting the heat conversion means where excess heat is dissipated before being returned to the heat conversion means. In any arrangement, the radiator may also receive fluid from a storage tank and the fluid may be water.

In a further arrangement of the eighth aspect, the apparatus may comprise a flow control means adapted to control the flow rate of the fluid through the heat conversion means to control the exit temperature of the fluid as it leaves the heat conversion means. The flow control means may comprise one or more temperature sensors to monitor the temperature of the fluid entering and leaving the heat conversion means. The flow control means may be a thermostatically adjusted circulating pump with variable flow rate.

According to a ninth aspect, there is provided a solar collection system. The system may comprise first and second support portions. The system may further comprise at least one reflector (which may be a primary reflector) supported by the first support portion. The primary reflector may comprise a first axis and a second axis normal to the first axis. The primary reflector may be arcuate about both the first and second axes. The reflector may including a concave reflector surface, wherein the reflective surface curves about the first axis and second axis, the second axis being in a plane generally normal to the first axis and curved about the first axis. The primary reflector may be adapted for focusing radiation incident thereon to a focal point or area. The system may further comprise at least one photovoltaic cell supported by the second support portion. The photovoltaic cell may be positioned to receive for receiving radiation incident on the at least one primary reflector for conversion of the radiation to both electrical and heat energy. The photovoltaic cell may be disposed at or proximal to the focal point or area. The at least one photovoltaic cell may be in operative engagement with a respective primary reflector; an electrical conversion means operatively coupled with the photovoltaic cell for conversion of direct current electrical power generated in the photovoltaic cell to alternating current electrical power. The system may further comprise a heat conversion means comprised in the second support portion for converting excess solar radiation energy incident thereon to heat energy. The photovoltaic cell may be in thermal communication with the inner support portion for transferring excess solar radiation incident on the photovoltaic cell to the heat conversion means by conductive heat transfer.

According to an arrangement of the ninth aspect, there is provided a solar collection system comprising: first and second support portions; at least one reflector (which may be a primary reflector) supported by the first support portion, said primary reflector the reflector including a concave reflector surface, wherein the reflective surface curves about a first axis and second axis, the second axis being in a plane generally normal to the first axis and curved about the first axis; at least one photovoltaic cell supported by the second support portion, said photovoltaic cell positioned to receive radiation incident on the at least one primary reflector for conversion of the radiation to both electrical and heat energy, wherein the at least one photovoltaic cell is in operative engagement with a respective primary reflector; an electrical conversion means operatively coupled with the photovoltaic cell for conversion of direct current electrical power generated in the photovoltaic cell to alternating current electrical power; a heat conversion means comprised in the second support portion for converting excess solar radiation energy incident thereon to heat energy, wherein photovoltaic cell is in thermal communication with the inner support portion for transferring excess solar radiation incident on the photovoltaic cell to the heat conversion means by conductive heat transfer.

The system may further comprise at least one secondary reflector in constant optical working engagement with a corresponding primary reflector and a respective photovoltaic cell such that it is adapted to direct solar radiation incident thereon from primary solar concentrating the secondary reflector adapted for receiving and redirecting solar radiation from the corresponding primary reflector on to the respective photovoltaic cell, where such radiation would otherwise have not been incident on the photovoltaic cell, thus contributing to the electrical and heat generation of the apparatus and increasing the conversion efficiency of the incident radiation to wither electrical or heat energy.

The system may comprise two arrays of primary reflectors and respective photovoltaic cells, each array comprising a plurality of reflectors each fixedly attached to the first support portion, wherein each arrays being attached to opposing sides of the first support portion. In a particular arrangement, each array of primary reflectors may comprise a continuous reflective sheet having a plurality of concave reflective surfaces in operative engagement with a respective photovoltaic cell.

The heat conversion means may comprise a hollow portion or duct and a pump for flowing a fluid through the hollow portion or duct, wherein in use said fluid is heated by excess solar radiation incident on the inner support portion and excess solar radiation incident on the photovoltaic cell. The system may further comprise a fluid outlet for extracting heated fluid for domestic or commercial use.

The primary reflector may be elongate, wherein the first axis may be aligned along a longitudinal dimension of the primary reflector, and the second axis may be aligned along a transverse dimension of the primary reflector.

In arrangements of any of the aspects disclosed herein, the at least one (primary) reflector(s) or the at least one primary solar concentrating element(s) of the apparatus, respectively, may be a reflector, and may be adapted for reflective solar radiation. The solar reflector may comprise a reflective film. The solar reflector may have an inner surface and an outer surface, the inner surface being reflective. The reflective film may be disposed on the inner surface of the solar reflector. The reflective film may be a weatherproof Aluminium sheet (e.g. MIRO-SUN 90 weatherproof, 0.3 mm thick). The reflective film may be removable and replaceable.

In particular arrangements, the solar reflector may be an elongate solar reflector. The elongate solar reflector may have an arcuate cross-section about at least a first axis corresponding to a first dimension. The elongate solar reflector may have an arcuate cross-section in two dimensions. In other arrangements, in a first dimension aligned along a first axis, the elongate solar reflector may have a cross-section selected from the group of a circular cross-section (i.e. a segment of a circle), a parabolic cross section; an elliptical cross-section; or a hyperbolic cross-section. In a second dimension with respect to a second axis, second axis being in a plane generally normal to the first axis and curved about the first axis, the elongate solar reflector may have a cross-section selected from the group of; a circular cross-section (i.e. a segment of a circle), a parabolic cross section; an elliptical cross-section; or a hyperbolic cross section. In a particular example arrangement, the elongate solar reflector may comprise a parabolic cross-section along a first axis and a circular (i.e. a segment of a circle) cross section along a second axis normal to the first axis. The elongate solar reflector may comprise a segment of a parabolic reflector. The elongate solar reflector may comprise an elongate segment of a parabolic dish reflector. The elongate solar reflector may comprise: a parabolic profile along the first axis (e.g. in the longitudinal direction for the elongate primary reflector); and a circular (i.e. a segment of a circle) profile along the second axis (e.g. in the transverse direction for the elongate primary reflector). The elongate solar reflector may comprise: a circular (i.e. a segment of a circle) profile in the longitudinal direction; and a circular (i.e. a segment of a circle) profile in the transverse direction. The elongate solar reflector may comprise: a curved profile in the longitudinal direction which is intermediate between a circular (i.e. a segment of a circle) and a parabolic profile; and a circular (i.e. a segment of a circle) profile in the transverse direction. The circular profile of any of the above arrangements may be a semi-circular or partially circular profile, wherein the semi-circular profile comprises a circular arc of about 180 degrees and a partially circular profile comprises a circular arc of less than 180 degrees, for example an arc subtending an angle of between about 5 degrees and about 180 degrees from a point.

In example arrangements of any of the first to ninth aspects, the elongate solar reflector may have dimensions of between about 15 and 35 cm wide and between about 60 cm to 100 cm long. In other example arrangements of any of the first to sixth aspects, the elongate solar reflector may have dimensions of about 25 cm wide and about 80 cm long. There may also be a narrow gutter running longitudinally along the elongate solar reflector to allow drainage of any rain and dust.

In further arrangements, the apparatus of any of the second to ninth aspects may further comprise at least one secondary solar concentrating element. The secondary solar concentrating element may be in constant optical working engagement with a respective primary reflector or primary solar concentrating element and a respective photovoltaic cell for concentrating input solar optical radiation incident on the respective primary reflector or primary solar concentrating element on to the respective photovoltaic cell. The secondary solar concentrating element may be at least one secondary reflector or refractor. The at least one secondary reflector or refractor may be fixedly engaged on the second support portion of the support frame. The at least one secondary reflector may comprise a mirrored surface. The at least one secondary reflector may comprise a reflective film. The at least one secondary reflector may have an inner surface and an outer surface, the inner surface being reflective. The reflective film may be disposed on the inner surface of the secondary reflector. The reflective film may be a weatherproof Aluminium sheet (e.g. MIRO-SUN 90 weatherproof, 0.3 mm thick). The at least one secondary reflector or refractor may be frustum-shaped and may be a frustum. The frustum may have an inner and outer surface, the inner surface being reflective. The reflective film may be disposed on the inner surface of the frustum. The frustum may be disposed adjacent to its corresponding photovoltaic cell.

In the apparatus of any one of the arrangements of any of the second to ninth aspects, the concentration factor of the apparatus may be greater than 500 times. In some arrangements, the concentration factor of the apparatus may be greater than 1000 times. In some arrangements, the concentration factor of the apparatus may be in the range of between 900 times and 2500 times. In an example arrangement, the concentration factor of the apparatus may be in the range of between 1200 times and 1600 times. In another example arrangement, the concentration factor of the apparatus may be about 1450 times.

In any of the arrangements of any of the second to ninth aspects, the support frame of the apparatus may be supported by at least one pivot rotatable in at least two directions. The pivot may be located proximal to or on the horizontal axis of the centre of gravity of the apparatus.

The apparatus may further comprise solar tracking means for moving the support frame about the pivot to adjust an elevation angle of the apparatus and a horizontal angle of the apparatus with respect to changes in the direction of incident solar radiation over a daylight period, thereby to track the apparent sun's motion across the sky.

The photovoltaic cell may be a III-V triple junction concentrating photovoltaic (“CPV”) cell. The CPV cell may be a GaInP/GaInAs/Ge cell or a InGaP/GaAs/Ge cell or other suitable triple junction cell.

An apparatus of the invention combines the necessary CPV heat removal with productive use of the low-grade heat as hot water. The primary reflector or primary solar concentrating element may be a solar reflector. The solar reflector may concentrate light to a point as required for a 10×10 mm CPV cell. A parabolic dish reflector is the simple geometric form required to focus light to a point. A solar reflector of the invention may comprise a rectangular segment of a parabolic dish form. Two or more solar reflectors may be mounted side-by-side down both sides of a central support frame comprising first and second support portions. The central support frame may also support a centrally mounted receiver tube. There may be one or more solar reflectors mounted on each side of the central support frame. There may be 2, 3, 4, 5, 6, 7, 8, 9, 10, 11, 12, 13, 14, 15, 16, 17, 18, 19, 19, 20, 21, 22, 23, 24, 25, 26, 27, 28, 29, 30, 35, 40, 45, 50, 60, 70, 80, 90, 100 or more solar reflectors mounted on each side of the central support frame. A CPV cell may be mounted on the receiver tube near the focal point (or area) of each solar reflector along the length of and on either side of the receiver tube. In use each solar reflector focuses and thereby concentrates solar light onto its respective CPV cell. Heat is conducted away from the CPV cell by a heat transfer fluid circulating through the tube (the heat transfer fluid may be water or some other heat transfer fluid). The apparatus of the invention provides a high concentration of sunlight on a CPV cell. The apparatus of the invention may comprise means for 2-axis tracking of the sun by the solar reflector(s). Whilst tracking adds to the system cost, it also adds 10-30% to the total amount of power generated in kWhrs for the same PV system peak power rating. This translates into an approximate 30% reduction in the required PV system installed peak power rating compared to standard PV. An essential component of the apparatus of the invention is the CPV cell. The CPV cell is a minority cost of the whole apparatus. An apparatus of the invention is designed around a single high-tech component; the commercially available CPV cells. EMCORE and SpectroLab (±Cyrium) supply similar CPV cells, with a 20 year limited manufacturers warranty, thus avoiding a sole provider monopoly and high technology development risk. The balance of system components (tracker, frame, mirror support, receiver, pole mount) can be built with widely available manufacturing technology. The solar reflector may comprise a thin film mirror (Alanod MIRO-SUN). The inventor has estimated the manufactured cost of an apparatus according to the invention to be cost competitive and profitable compared with current lowest cost retail PV panel market ($/watt). Consumers will gain by producing approximately 10-30% more power (kWhrs) for the same peak system power rating because of solar tracking. Consumers will also gain by having a solar hot water collector for free. Whilst PV module prices have been steadily falling for many years, CPV system prices are likely to fall more rapidly due to greater scope for high volume manufacturing and component price reductions. The apparatus of the invention has technical and cost advantages over conventional solar PV and hot water. To maintain competitive advantage in the solar PV (+T) market continual improvement is required. CPV cell manufacturers have steadily improved CPV cell efficiency to 39% with further efficiency increases to >40% likely in the next 18 months. Each CPV cell efficiency improvement can be incorporated into an apparatus of the invention without a change to the optical geometry or system re-design. Thermo-electric devices (opposite of peltier cooling for same devices, that is, if a temperature differential is applied across the device then a current is generated=power out) are commercially available with a narrow form factor of approx 3 mm thick by 25×25 mm (matches CPV cell) and may also be incorporated into an apparatus of the invention. The only issue is that the present efficiency is low so extra power production is also low at around 2 watts per cell. However, there is research underway which may improve efficiency and lead to economic utilisation of thermo-electric generators in conjunction with CPV cells in solar collectors such as an apparatus of the invention described herein. The apparatus of the invention is a new category of high efficiency, concentrating solar power and hot water providing additional market competition, greater kWhrs from tracking, and lower combined power and hot water system cost for the benefit of consumers and uptake of distributed renewable energy.

The optical devices in arrangements of the present invention are applicable to a broad range of optical devices technologies and can be fabricated from a variety of optic materials. The following description discusses several embodiments of the optical devices of the present invention as implemented in reflective arrangements, since the majority of currently available optical devices are fabricated in reflective optics and the most commonly encountered applications of the present invention will involve reflective optics. Nevertheless, the present invention may also advantageously be employed in refractive, diffractive, holographic, and combinations of reflective and the aforementioned technologies. Accordingly, the present invention is not intended to be limited to those devices fabricated in reflective optics, but will include those devices fabricated, alone or in combination, in one or more of the available optic methods and technologies available to those skilled in the art

### BRIEF DESCRIPTION OF THE DRAWINGS

Arrangements of the solar collector will now be described, by way of an example only, with reference to the accompanying drawings wherein:

FIG. 1 is a schematic arrangement of an apparatus for collection and utilisation of solar energy as described herein;

FIG. 2A is a perspective view of an example schematic arrangement of an apparatus for collection and utilisation of solar energy with four primary solar concentrating elements in two arrays as described herein;

FIG. 2B is a further perspective view of the schematic arrangement of the apparatus of FIG. 2A as described herein;

FIG. 2C is a schematic of the second support portion of the apparatus of FIG. 2A;

FIG. 2D is a further perspective view of the arrangement of FIG. 2A illustrating the relationship between the reflective surface of the primary solar concentrating elements and the first and second axes about which the reflective surface is curved;

FIGS. 3A and 3B are a top view of example arrangements of apparatus for collection and utilisation of solar energy comprising two arrays of primary solar concentrating elements;

FIG. 4 is a schematic of an example primary solar concentrating element of the apparatus' described herein;

FIGS. 5A and 5B are respectively top down and perspective representations of a parabolic dish reflector, a segment of which may be used to form the solar reflectors of the arrangements of the apparatus described herein;

FIG. 6A is a further arrangement of the second support portion of the apparatus of FIG. 2A comprising a secondary reflector;

FIG. 6B is a graph of overall collection efficiency (%) with and without use of a secondary reflector.

FIG. 6C and FIG. 6D respectively are front and rear perspective views of an example frustum-shaped secondary reflector.

FIGS. 6E and 6F are two examples of methods for mounting the secondary reflector to the inner portion of the second support portion.

FIGS. 6G and 6H are respectively two example radiation flux distributions across the photovoltaic cell.

FIG. 7 is a cross-section view of an example arrangement of a heat transfer means adaptable for extracting heat generated in the apparatus for collection and utilisation of solar energy.

FIGS. 8A through 8G are various views of an example apparatus for collection and utilisation of solar energy.

FIG. 9 is a front perspective view of an alternative example apparatus for collection and utilisation of solar energy.

FIG. 10 is a front perspective view of another alternative example apparatus for collection and utilisation of solar energy.

FIG. 11 is a front perspective view of yet another alternative example apparatus for collection and utilisation of solar energy.

FIG. 12 is a front perspective view of another alternative example apparatus for collection and utilisation of solar energy with detail showing frustum-shaped secondary reflector.

FIG. 13A is a perspective view of a modular extrusion for use in the support frame of the apparatus, wherein FIG. 13B is schematic showing connection of two such extrusions, and FIG. 13C is a detail of the apparatus of FIG. 12 showing a plurality of such extrusions in use to form the support frame for the primary reflectors of the apparatus.

FIG. 14 is a front perspective view of another alternative example apparatus for collection and utilisation of solar energy with detail showing frustum-shaped secondary reflector.

FIG. 15 is a flow diagram of a system for collection and utilisation of solar energy according to the present invention.

### DEFINITIONS

The following definitions are provided as general definitions and should in no way limit the scope of the present invention to those terms alone, but are put forth for a better understanding of the following description.

Unless defined otherwise, all technical and scientific terms used herein have the same meaning as commonly understood by those of ordinary skill in the art to which the invention belongs. For the purposes of the present invention, the following terms are defined below.

The articles “a” and “an” are used herein to refer to one or to more than one (i.e. to at least one) of the grammatical object of the article. By way of example, “an element” refers to one element or more than one element.

The term “about” is used herein to refer to quantities that vary by as much as 30%, preferably by as much as 20%, and more preferably by as much as 10% to a reference quantity.

Throughout this specification, unless the context requires otherwise, the words “comprise”, “comprises” and “comprising” will be understood to imply the inclusion of a stated step or element or group of steps or elements but not the exclusion of any other step or element or group of steps or elements.

Throughout the specification and claims the terms “primary reflector(s)” and “primary solar concentrating element(s)” can be used interchangeably.

Although any methods and materials similar or equivalent to those described herein can be used in the practice or testing of the present invention, preferred methods and materials are described. It will be appreciated that the methods, apparatus and systems described herein may be implemented in a variety of ways and for a variety of purposes. The description here is by way of example only.

### DETAILED DESCRIPTION

All concentrating solar collectors have a similar design philosophy; that is, to reduce the area of expensive photovoltaic material by concentrating light with a comparatively cheap mirror or lens. To achieve a significantly lower system cost of electricity (i.e. cost per watt) than conventional flat PV modules, mass-manufacturing costs of system components are greatly reduced.

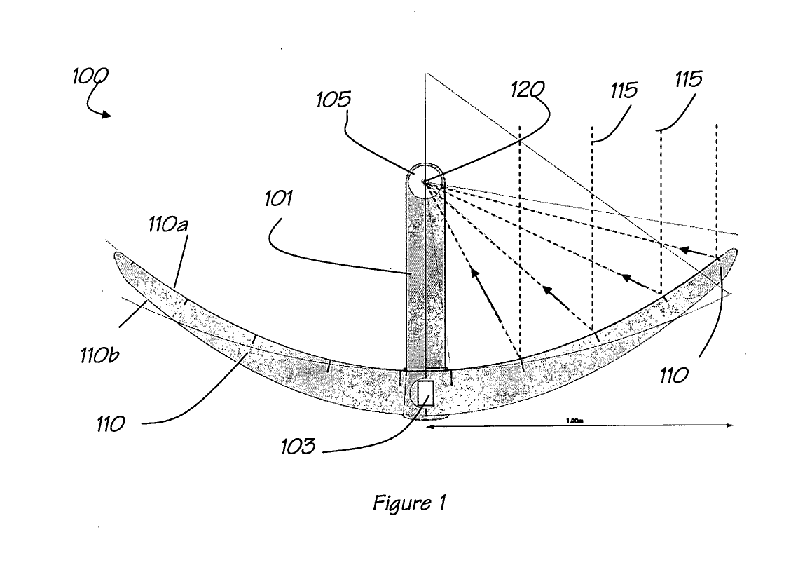

Referring to FIG. 1, there is provided an apparatus 100 for collection and utilisation of solar energy. The apparatus may comprise a support frame 101 comprising first and second support portions 103 and 105 respectively. The first and second support portions are separated and fixedly interconnected by the support frame 101. Support frame 101 may comprise aluminium, stainless steel, mild steel, galvanised iron, or other suitable materials. The apparatus 100 further comprises at least one primary solar concentrating element 110 fixedly attached to the first support portion 105 of support frame 101. The at least one primary solar concentrating element 110 is an elongate solar reflector having an inner surface 110a and an outer surface 110b, the inner surface 110a being reflective. The apparatus 100 further comprises at least one respective photovoltaic cell 120 fixedly attached to the second support portion 105. The primary solar concentrating element(s) 110 are adapted to receive incoming solar radiation 115 and direct the solar radiation to the respective photovoltaic cell 120. The photovoltaic cell 120 is adapted to receive the solar radiation 115 which is incident upon the inner surface of 110a of the primary solar concentrating element(s) 110 and convert such radiation 115 to electrical energy. The support frame 101 is adapted to maintain a constant optical working relationship between the at least one primary solar concentrating element 110 and the respective photovoltaic cell 120.

Example photovoltaic cells that may be suitable for use in the present apparatus include high efficiency (38%) triple junction solar cells for terrestrial concentrating solar applications, which are available commercially from two US suppliers, for example Emcore of Albuquerque, N. Mex., United States or Spectrolab of Sylmar, Calif., United States.

Arrangements of the apparatus for collection and utilisation of solar energy are designed to provide a simple geometric arrangement for concentrating sunlight (1,000 suns concentration factor) onto a high efficiency (38%) photovoltaic cell with active heat removal. In an example arrangement, sunlight is reflected off a parabolic primary solar concentrating element (80×25) cm curved in 2 directions onto a (1×1) cm terrestrial triple junction solar cell close to the focal point. Multiple primary solar concentrating elements (e.g. 2, 4, 5, 10 or 20) are arranged along a structural support to form the solar collector, where one primary solar concentrating element is likely to produce about 50 watts peak electrical power. A heat conversion means is located along a line close to the focal point where the photovoltaic cells are mounted. Water may be pumped through the heat conversions means through a thermostatically controlled circuit to keep the photovoltaic cells at or below about 70 deg Celsius. Hot water from the heat conversion means flows to the hot water storage tank and back to the main structural support of the apparatus, which also serves the purpose of a radiator tube. Details of key system components are described below.

When more sunlight falls on a triple junction cell its voltage stays approximately the same 2.5 V per cell but the current increases to approx 20 Amps under 1,000 times concentration. As will be appreciated, multiple cells may be joined in series to increase the voltage, with each cell being coupled to a respective primary concentrating element. In this arrangement a suitable low voltage inverter is required since many solar panel inverters are adapted for higher voltages obtained from existing flat panel arrangements. A low voltage inverter which may be suitable for the present apparatus' described herein is available from Latronic Sunpower Pty. Ltd., Moffat Beach, Queensland, Australia.

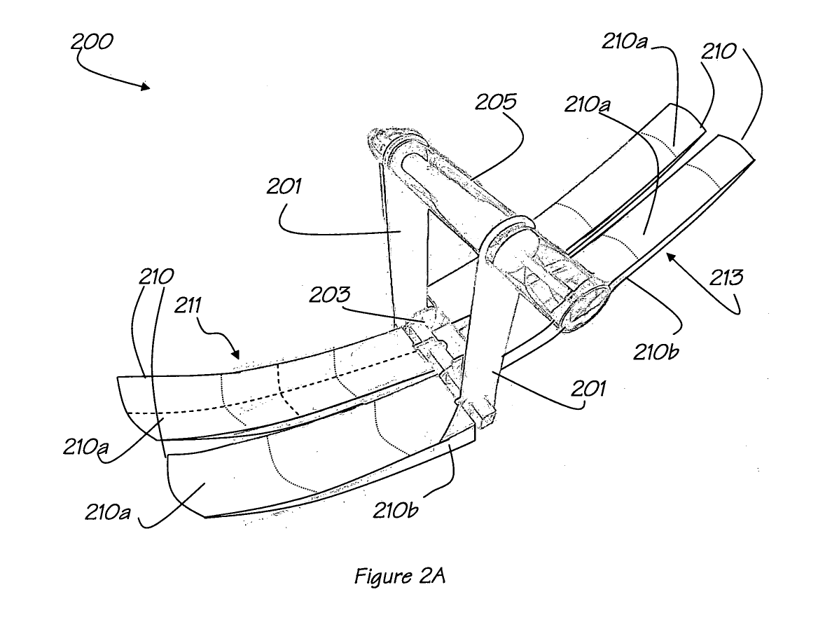

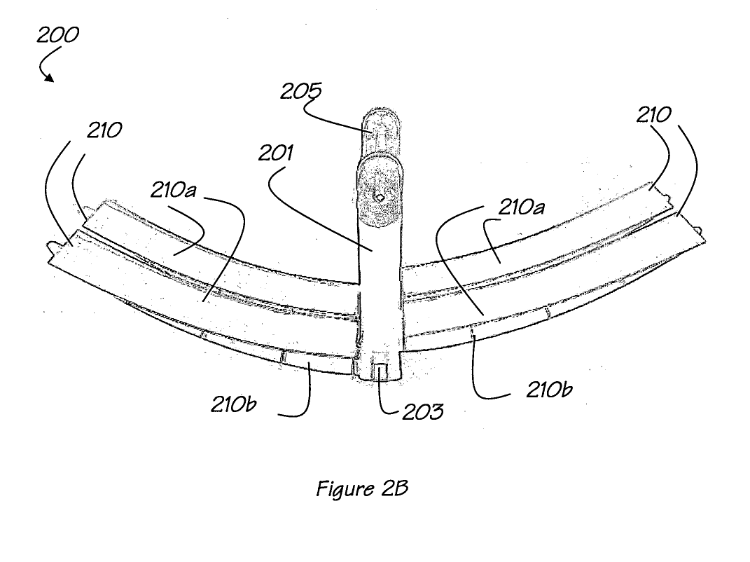

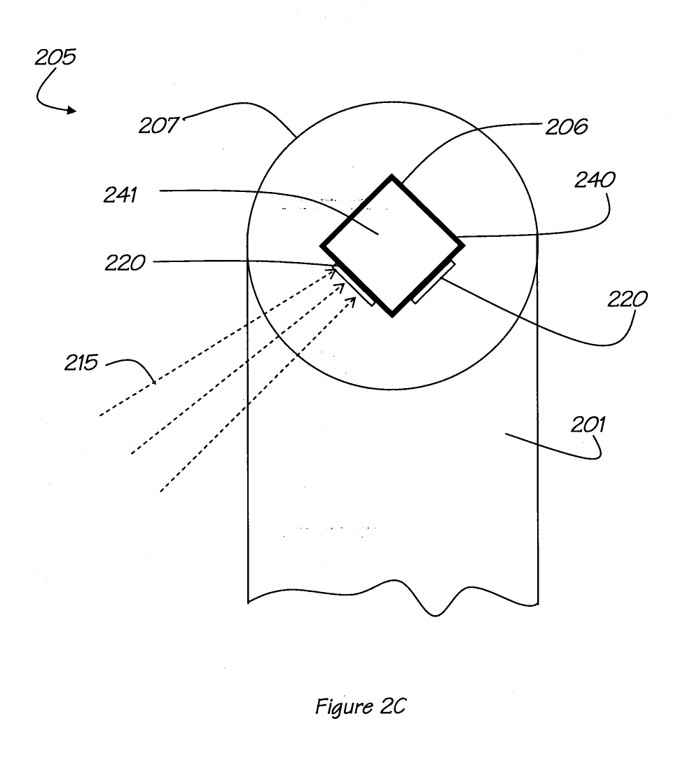

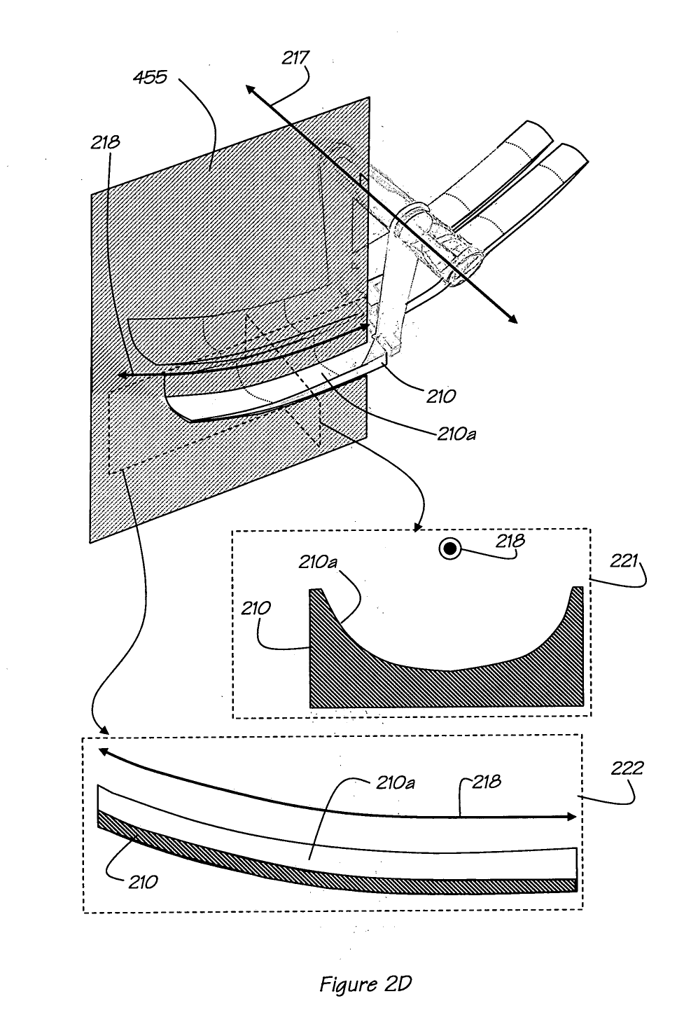

In a further arrangement as depicted in FIGS. 2A and 2B, apparatus 200 may further comprise a plurality of like primary solar concentrating elements 210 fixedly attached to and arrayed along the elongate first support portion 203. In this arrangement, the apparatus 200 may further comprise a plurality of respective photovoltaic cells (not shown) fixedly attached to and arrayed along the second support portion 205. In this arrangement, each of the plurality of primary solar concentrating elements may be maintained by the support frame in constant optical working relationship with a respective photovoltaic cell.

The apparatus 200 comprises two arrays 211 and 213 of solar concentrating elements 210 being fixedly attached to opposing sides of the first support portion 203. As depicted in FIGS. 2A and 2B, such arrays comprising at least two adjacent like primary solar concentrating elements 210. The solar concentrating elements 210 are elongate solar reflectors having an inner surface 210a and an outer surface 210b, the inner surface 210a being reflective. The reflective surface 210a of solar concentrating elements 210 are curved about first and second axes 217 and 218 respectively, wherein the second axis 218 is in a plane 219 generally normal to the first axis 217 and curved about the first axis 217 as depicted in FIG. 2D, wherein the second axis 218 follows a parabolic path in the plane 219. Insets 221 and 222 of FIG. 2D respectively show transverse and longitudinal cross-sections of a concentrating element 210 illustrating the relationship between the second axis 218 and the reflective surface 210a in each dimension. Apparatus 200 further comprises a plurality of respective photovoltaic cells (not shown) fixedly attached to the second support portion 205 and in constant optical working engagement with a respective solar concentrating element 210. Each cell is associated with a respective reflector 210 and positioned relative to the reflector surface of its associated reflector to receive radiation reflected by the associated surface and to convert the received radiation to electrical energy. In further arrangement, the apparatus may comprise additional concentrating elements, and where such additional elements are present, the solar concentrating elements 210 are termed primary concentrating elements or reflectors, since they are surface which reflects the incoming solar radiation. The apparatus may further comprise secondary and/or tertiary concentrating elements (not shown), which may be reflective elements, refractive elements, diffractive elements, holographic elements or the like as would be appreciated by the skilled addressee.

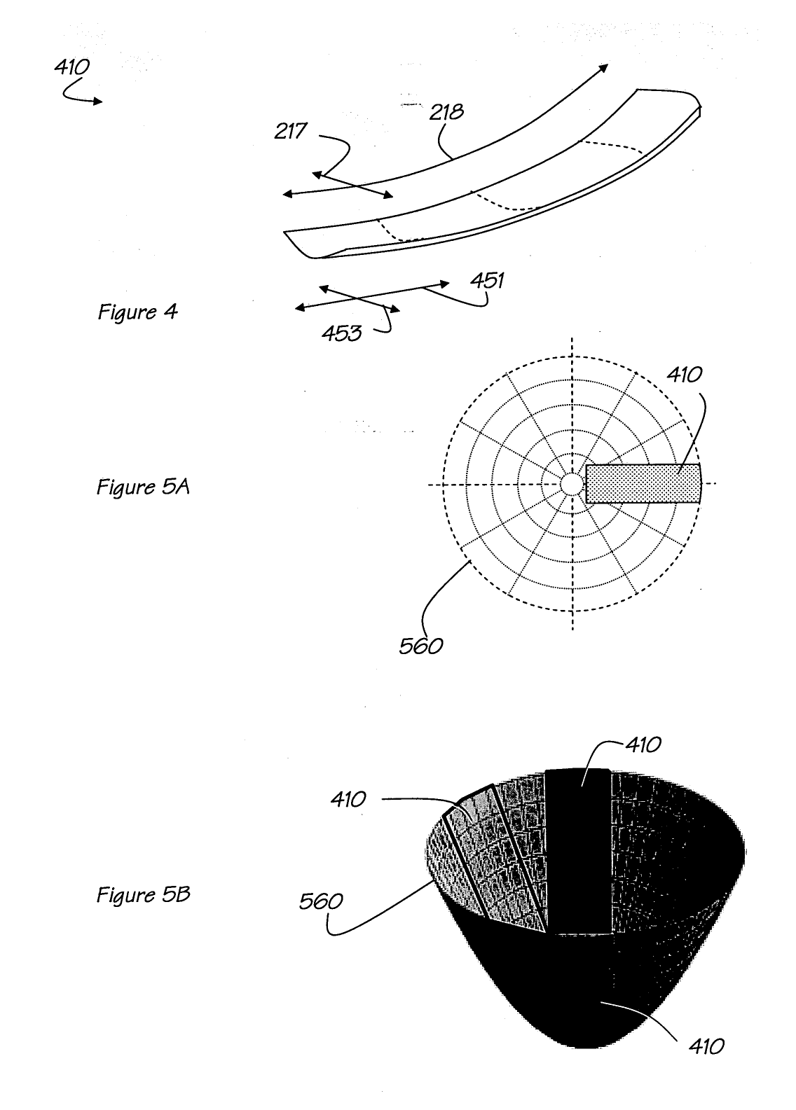

In arrangements of the solar collector apparatus' described herein, each of the at least one primary solar concentrating element(s) (110, 210, 310, 810, 910, 1010, 1110, 1210, 1410) are elongate solar reflectors having a reflective inner surface 110a, 210a, 310a, 810a, 910a, 1010a, 1110a, and 1210a) adapted for reflection of incident solar radiation. The reflective inner surface may be adapted to reflect solar radiation in the visible and/or near infrared regions of the solar radiation spectrum. The reflective inner surface may comprise a reflective film. The reflective film may be a weatherproof Aluminium sheet (e.g. MIRO-SUN 90 weatherproof, 0.3 mm thick). The reflective film may be removable and replaceable. In particular arrangements, such as those depicted in FIGS. 1 to 3, the inner surface 110a, 210a, and 310a, of primary solar concentrating elements 110, 210 and 310 may have an arcuate cross-section in at least one dimension, and preferably is arcuate in two dimensions. An example elongate solar reflector 410 is depicted in FIG. 4. For example, in a first (e.g. longitudinal) dimension 451, the elongate solar reflector(s) 410 may have a cross-section selected from the group of; a circular cross-section (i.e. a segment of a circle), a parabolic cross section; an elliptical cross-section; or a hyperbolic cross-section, and is preferably either circular or parabolic. In a second (e.g. transverse) dimension 453, the elongate solar reflector may have a cross-section selected from the group of a circular cross-section (i.e. a segment of a circle), a parabolic cross section; an elliptical cross-section; or a hyperbolic cross section. First and second axes 217 and 218 (refer to FIG. 2D) are shown for reference. In a particular example arrangement FIG. 4, the elongate solar reflector 410 has a parabolic cross-section in the first dimension 451 and a circular cross section in the second dimension 453. In other arrangements, the solar reflector 410 may have a parabolic cross-section in the second dimension 453. In a particular arrangement, the elongate solar reflector 410 may comprise a segment of a parabolic reflector. Such an elongate solar reflector 410 may be formed, for example by taking an elongate segment of a parabolic dish reflector 560 as depicted schematically in FIGS. 5A and 5B respectively shown in top-down and perspective views. Alternatively, the profile of the reflective surfaces of elongate solar reflector 410 in each dimension 451 and 453 may be separately optimised for efficient reflection of incident solar radiation to the photovoltaic cells 220 (FIG. 2C) supported by the second support portion 205 (FIGS. 2B and 2C) of support frame 201 (FIGS. 2B and 2C). For example, the profile of the reflector surface in each dimension may be altered such that it deviates from a parabolic (or circular) profile. Such reflectors with altered reflector surface profiles may be advantageous for optimising the image projected by the reflector surface onto the receiving area of an associated photovoltaic cell, for example, to provide a substantially uniform irradiated flux density of reflected light over the cell receiving area. In example arrangements, the elongate solar reflector 410 (FIG. 4) may have dimensions of between about 15 and 35 cm wide (i.e. in dimension 453) and between about 60 cm to 100 cm long (i.e. in dimension 451). In other arrangements, the apparatus comprises an array comprising a plurality of reflectors (each reflector as per elongate solar reflector 410) formed as a continuous reflective sheet having a plurality of concave reflective surfaces in operative engagement with a respective photovoltaic cell. In this arrangement, the array of reflectors may have dimensions of between about 75 and 300 cm wide (i.e. in dimension 453) and between about 60 cm to 100 cm or more in dimension 451.

In the apparatus of any one of the arrangements disclosed herein, the concentration factor of the apparatus, determined by the efficiency in the collection of incident solar radiation on the apparatus and received by the photovoltaic cells may be greater than 500 times (i.e. 900 suns concentration factor). This is many times greater than most typical Si PV solar concentrator devices, which usually only operate at very low concentration factors (eg about 5 to 50 times, and for the use of triple junction cells high concentration factors in the range of between 500 times and 1000 times are used in other solar collectors). In some arrangements, the concentration factor of the apparatus may be greater than 1000 times and may be in the range of between 900 times and 2500 times. In an example arrangement, the apparatus may be designed or optimised to have a concentration factor in the range of between 1200 times and 1600 times. In another example arrangement, the apparatus may be designed or optimised to have a concentration factor of about 1450 times. This concentration factor is generally a factor of the dimensions of the total collecting area of the apparatus. In the present example, approximate dimensions of (25×80) cm=2000 cm² are assumed. Additional factors which limit the concentration factor include the conversion from lineal planar dimensions to the collecting aperture directly facing the sun, and optical losses from the reflectivity of the primary mirror and glass tube. These factors reduce the incident theoretical maximum sunlight concentration factor to 1450 suns for an apparatus of the above dimensions, however, this figure may be reduced further due to losses from circum-solar radiation (dispersion through the atmosphere). A similar apparatus having different dimensions and increased or decreased total collecting area will have correspondingly increased or decreased theoretical maxima as would be appreciated by the skilled addressee. By limiting the concentration factor slightly from the theoretical maximum, this places less stringent requirements on the optimisation of the apparatus and thus keeps design and production costs to an acceptable commercially viable level.

In a particular example prototype arrangement as depicted in FIGS. 2A and 2B, to achieve a point (or area) focus onto the photovoltaic cells, a solar concentrator has been made into primary solar concentrating elements 210. Each element 210 has its respective photovoltaic cell 220 evenly distributed along a linear heat conversion means (not shown) in the second support portion 205. Several small-scale (4 element) versions of the solar collector have been built to assess construction methods, materials and primary mirror optical accuracy. In summary methods of bending 20×80 cm or 20×100 cm sheet acrylic mirror onto a CNC cut polymer frame does not produce sufficient optical accuracy with ease of assembly. In some arrangements, the primary solar concentrating element 210 may be three-dimensionally thermo-formed or injection moulded to achieve the desired design shape of the reflective surface thereof. The moulding may alternatively comprise a plurality of concave formations in the sheet mirror, to form a plurality of concave reflective surfaces forming an array of concentrating elements. Commercially available thin film mirror coatings designed for solar concentrators allow the mirror to be manufactured from standard industrial polymers with a thin protected mirror coating.

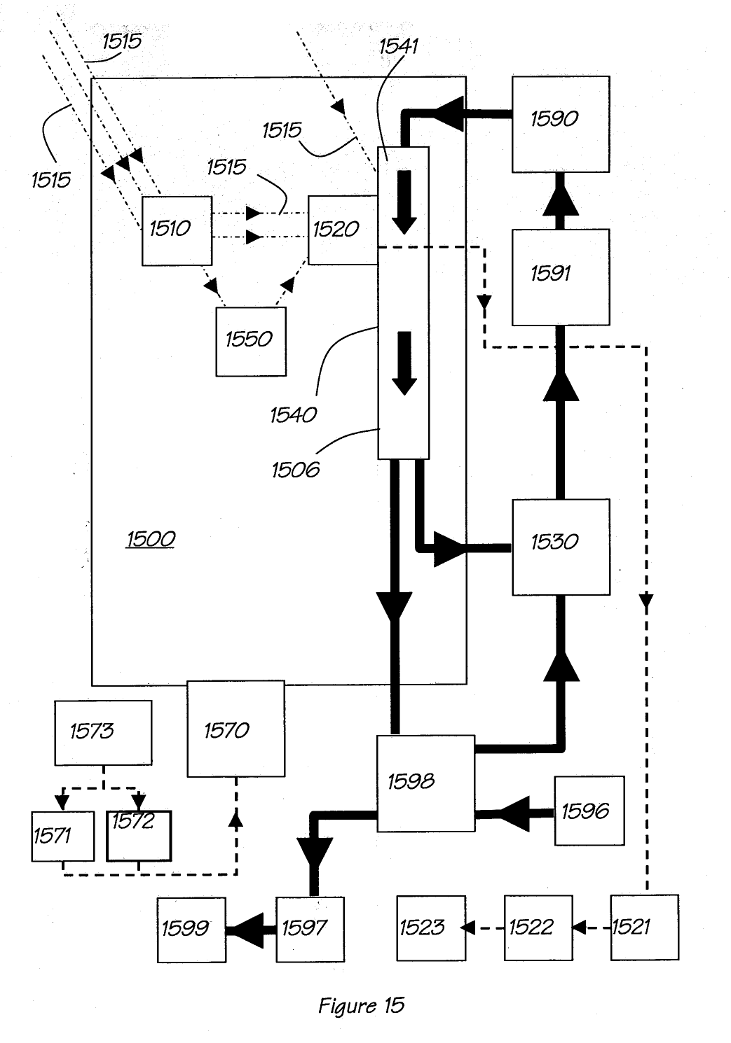

Returning now to FIG. 2C, there is shown a close-up view of an example arrangement of the second support portion 205 of support frame 201. In this arrangement, second support portion 205 comprises an inner portion 206 and an outer portion 207. Inner portion 206 is a rigid support member and may be hollow. The hollow inner portion 206 is adapted to permit a fluid flow therethrough. In use, the fluid flowing though inner portion 206 is heated by conductive heat transfer from the rear surface of photovoltaic cells 220, as discussed above and with reference to system 1500 of FIG. 15 below. Outer support member is substantially transparent to allow incoming solar radiation 215 to be incident on photovoltaic cell(s) 220. Outer support portion 207 is primarily designed as a protective shield for the photovoltaic cell(s) 220, to protect them (and any electrical connections to the cells 220) from environmental elements such as wind, rain, or tampering (e.g. damage by animals). The outer portion 207 may be a transparent tube, for example a glass tube, preferably having high optical transmission and low optical absorption to minimise optical losses as the radiation 215 reflected from the primary reflector(s) passes through tube 207 to be incident on cell(s) 220. In particular arrangements, the glass tube may have a diameter of about 150 mm, with a thickness of about 3 mm, and a refractive index of about 1.5. The glass tube may be formed from a low-iron content glass and may have an absorbance of about 1.5%. The glass tube will be a source of optical loss for radiation (e.g. sunlight) reflected from the primary reflector due to absorbance losses in the glass and also reflection losses. The glass tube may be anti-reflection coated to minimise reflection losses. In further arrangements, the transparent outer portion may comprise a tertiary concentrating element (not shown) incorporated therein to provide additional focusing/concentrating of incident radiation received by the primary reflectors onto the photovoltaic cells. The tertiary concentrating element may be a lens, Fresnel lens, or similar concentrating element as would be appreciated by to skilled addressee.

The photovoltaic cell(s) 220 are mounted such that they are in thermal communication with the inner support portion 206. In this manner, excess solar radiation incident on the photovoltaic cell in the form of heat is conducted to the hollow inner support portion 206 by heat transfer and therefore regulate the heat of photovoltaic cells 220 (photovoltaic cells are typically less efficient at elevated temperatures). This secondary optical element (outer support portion 207), which in some arrangements may be similar to an inverted light globe, is placed near the focal point of the primary solar concentrating elements and collects some additional circumsolar radiation and thereby also improves the system tolerance to tracking errors.

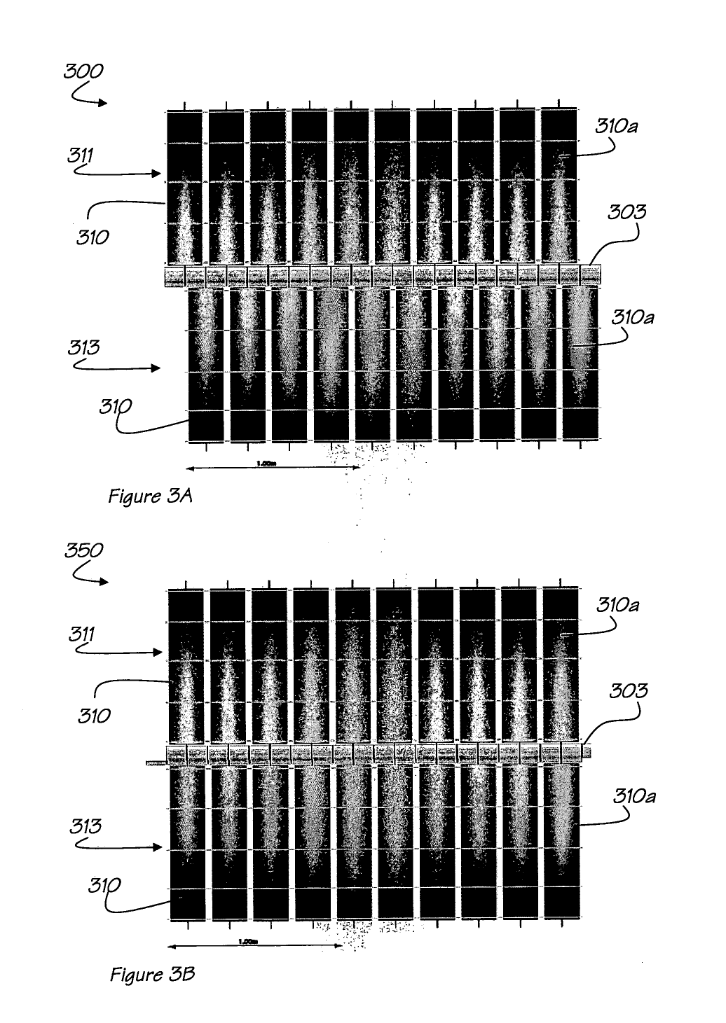

A further arrangement 300 of an apparatus for collection and utilisation of solar energy is depicted in FIG. 3A showing two arrays 311 and 313 of primary solar concentrating elements 310 having an inner surface 310a and an outer surface (not shown), the inner surface 310a being reflective, and each array comprising 10 individual primary elements 310 which are fixedly attached to the first support portion 303. FIG. 3B shows a further arrangement 350 where the primary concentrating elements 310 are not staggered as in FIG. 3A.

In such arrangements (e.g. apparatus 300 or 350), each of the primary solar concentrating elements 310 in the array may be separated from adjacent like solar concentrating elements by a distance of between about 5 to 40 cm. In other arrangements, each of the primary solar concentrating elements in the array may be separated from adjacent like primary solar concentrating elements by a distance of about 25 cm. Separation of the primary solar concentrating elements 310 has advantages since it reduces the wind load on the apparatus when installed, since the wind is dissipated by passing between adjacent primary concentration elements.

Although photovoltaic cells may be tolerant of high temperature (to >200° C.) (for example the commercially available triple junction CPV cells described above), the CPV cell efficiency declines by approx 1% for every 10 degrees above 25° C. Silicon photovoltaic cells are far less tolerant of high temperature and are generally not suitable for concentration systems greater than 50 times concentration factor due to the large amount of heat generated by these systems. The heat generated must be dissipated from high concentration photovoltaic systems such as those described herein to ensure efficient electrical power generation.

Thus, in particular arrangements of the solar collector apparatus' described herein, with reference to FIG. 2C the second support portion 205 further comprises a heat conversion means 240 for converting excess solar radiation energy incident thereon (typically incident on photovoltaic element(s) 220) to heat energy. For example, the heat conversion means 240 may comprise the hollow inner support portion 206 of second support portion 205, which may comprise a means (e.g. hollow portion (or duct) 241 of the inner support portion 206) for flowing a fluid therethrough. In use, the fluid is flowed through the second support portion 205 and is heated by the heat generated in the photovoltaic cells 220 caused by excess solar radiation incident thereon. Additional solar radiation may also be incident directly on the inner support portion 206 of second support portion 205 which may also contribute to heating the fluid flowing there through. The heated fluid, which may be water, may then be used for domestic or commercial application as described with reference to system 1500 depicted in FIG. 15.

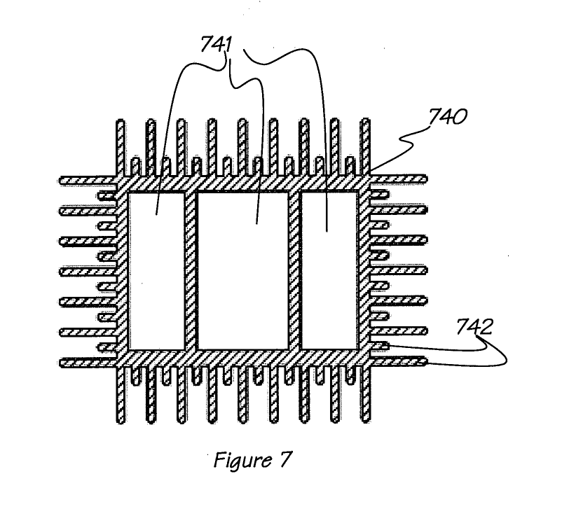

In a particular example arrangement, again with reference to FIG. 2C, the apparatus may employ a customised aluminium extrusion (e.g. the inner portion 206 of the second support portion 205) to mount the photovoltaic cell(s) 220 to and thus transfer heat generated in the photovoltaic cell(s) 220 to fluid (e.g. water) flowing through the hollow inner portion 206 (e.g. a tube). See, for example, FIG. 7 where there is depicted a cross-section view of an example arrangement of a heat conversion means 740 comprising hollow portions 741 for flowing fluid there through and fins 742 for dissipating heat. In particular arrangements, the fluid is water and the heat conversion means may be adapted to provide water at a temperature of greater than 50 degrees Celsius. The heat conversion means may be adapted to provide water at a temperature of between about 50 degrees Celsius and about 70 degrees Celsius. Such heat conversion means may be adapted to provide hot water for domestic or commercial use. Hot water exiting this heat conversion means may then be circulated to a normal storage tank. In an alternative arrangement, where the fluid is not water, the hot fluid exiting the heat conversion means may be passed to a heat exchanger in order to provide hot water for domestic or commercial use. If hot water is not required the heat must be dissipated before passing back to the absorption tube. In other arrangements, the main structural supports (i.e. the first support portion 203 or support frame 201 in FIG. 2A) for the apparatus may also comprise a heat radiator where hot water exiting the heat conversion means in the second portion is redirected and where excess heat is dissipated before being returned to the heat conversion means.

The apparatus may further comprise a flow control means (not shown) which is adapted to control the flow rate of the fluid through the heat conversion means 240 of FIG. 2C. The flow control means may also comprise one or more temperature sensors (not shown) to monitor the temperature of the fluid entering and leaving the heat conversion means 240. In this manner, the exit temperature of the fluid as it leaves the heat conversion means 240 can be controlled as required. The flow control means may be a thermostatically adjusted circulating pump with variable flow rate.

In further arrangements of the apparatus' described herein, each may further comprise at least one secondary solar concentrating element, where each of the at least one secondary concentrating elements is paired with and adapted to be in constant optical working engagement with a respective primary solar concentrating element and a respective photovoltaic cell. The primary aim of the secondary concentrating element(s) is for redirecting solar radiation incident and reflected from a respective primary solar concentrating element on to the respective photovoltaic cell, where such re-directed radiation would otherwise have not been incident on the photovoltaic cell.

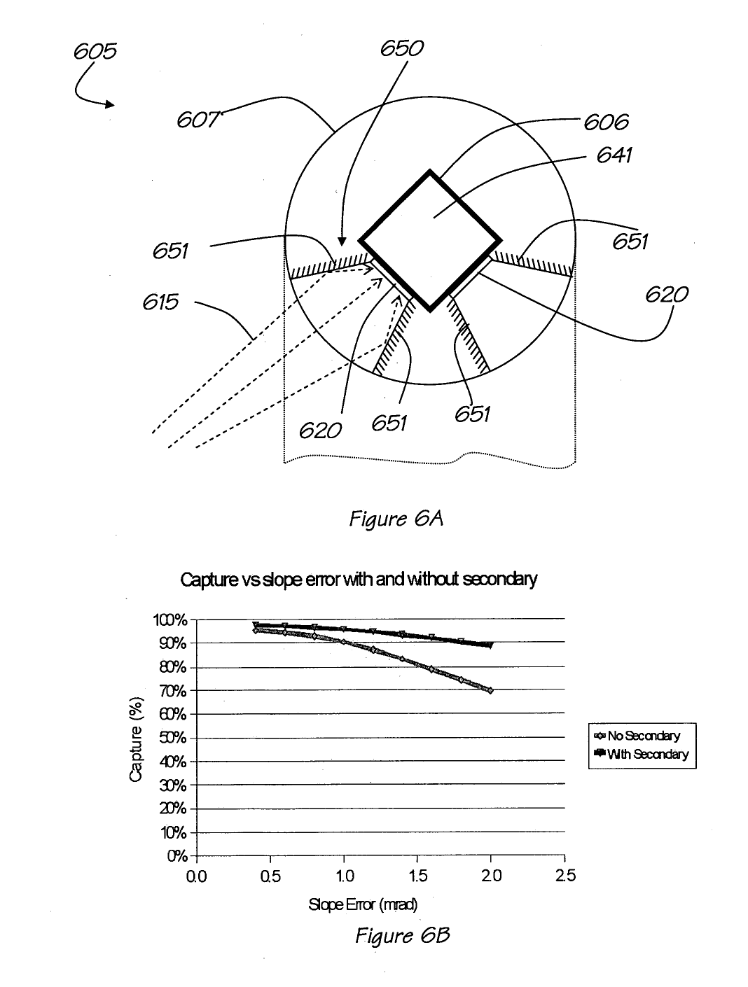

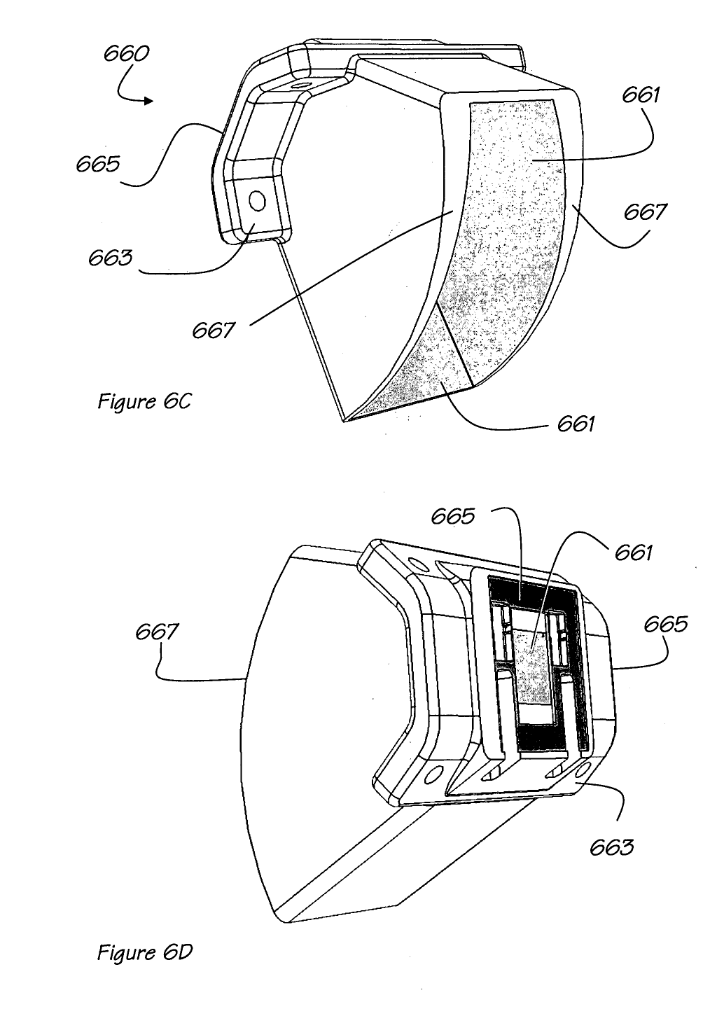

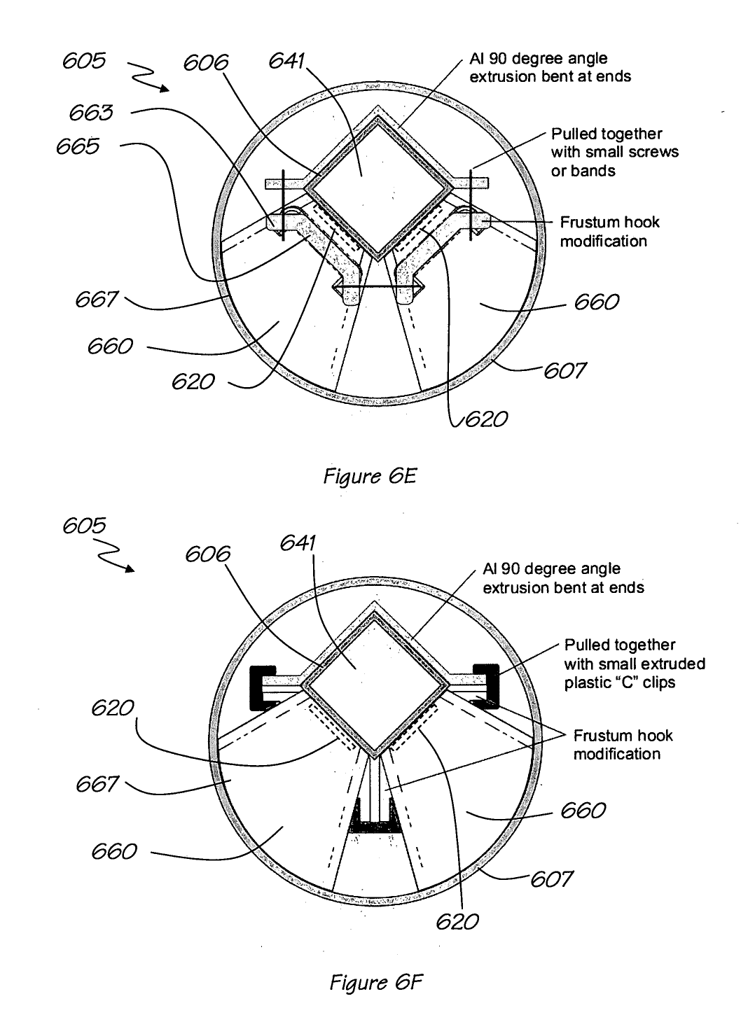

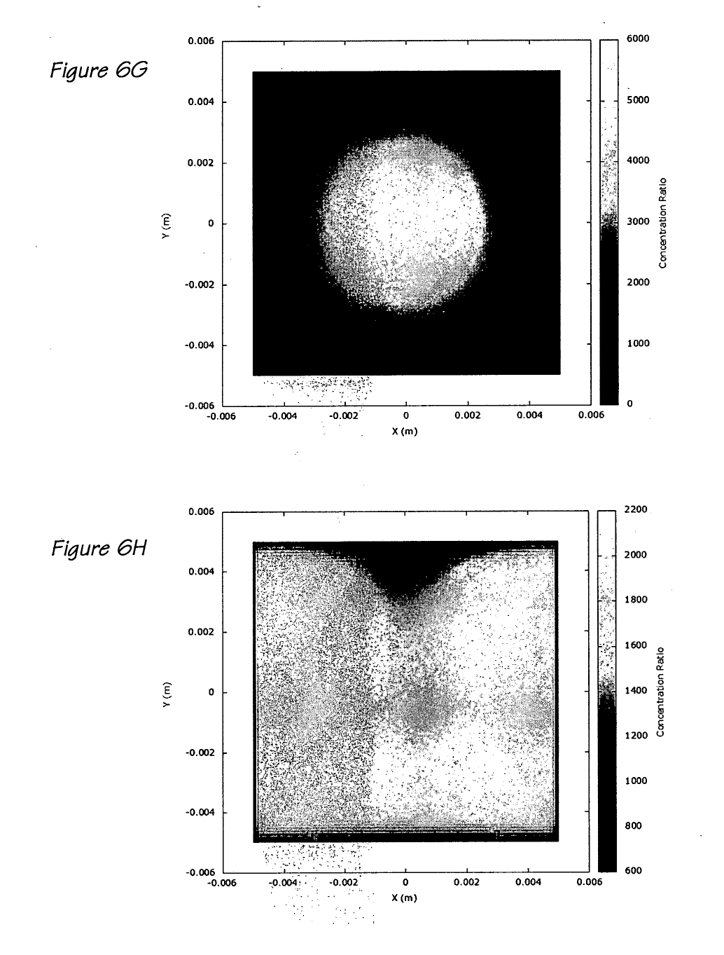

Referring to FIG. 6A, there is depicted a further arrangement 605 of the second support portion of the apparatus, which may be adapted to be incorporated in any one of the solar collector apparatus' described herein, comprising inner portion 606 (similar to that of inner portion 206 of FIG. 2) and transparent outer portion 607 (similar to that of outer portion 207 of FIG. 2). In this arrangement, the secondary solar concentrating element 650 comprises at least one, and preferably two secondary reflectors 651, the reflective surface of which may comprise a reflective film. The reflective film may be a weatherproof Aluminium sheet (e.g. MIRO-SUN 90 weatherproof, 0.3 mm thick). The at least one secondary reflector 651 may be fixedly engaged on the second support portion 605 of the support frame (e.g. see support frame 201 in FIGS. 2A and 2C). Incident radiation 615 from the primary solar concentrating element (not shown) that would otherwise miss the photovoltaic cell 620 is reflected by the secondary reflector 651 to be incident on the photovoltaic cell 620, thus contributing to the electrical and heat generation of the apparatus and increasing the conversion efficiency. In particular arrangements, the secondary concentrating element may be a reflector (or comprise a plurality of reflectors) having a reflectivity of about 90% or greater.

In other arrangements, the secondary concentrating element may, in addition to or alternative to reflective elements, comprise refractive elements (not shown). Suitable refractive elements may comprise a lens or Fresnel element situated so as to focus light onto the photovoltaic cell 620. It will be appreciated that by inclusion of a secondary concentrating element this may enable the optimisation parameters of, for example, the primary solar concentrating elements to be relaxed somewhat as small focusing errors may be corrected by the secondary concentration elements.

Preferably the secondary solar concentrating reflector 251 is frustum-shaped, for example, as depicted in FIGS. 6C and 6D. Secondary reflector 660 comprises reflective interior surfaces 661 to collect radiation received from an associated primary reflector and reflect such radiation onto the photovoltaic cell (i.e. cell 620 of FIG. 6A). Reflector 660 comprises a mounting formation 663 having a portion 665 adapted to abut the hollow portion 641 of inner portion 606 of the second support portion for mounting thereon. The rear of secondary reflector 660 of the present arrangement further comprises a recess 665 adapted to receive the photovoltaic cell 620 such that the rear of the photovoltaic cell 620 abuts with the inner portion 606 such that is in thermal communication therewith. Secondary reflector 660 of the present arrangement is further adapted such that the distal portions 667 thereof are configured to be contiguous with the inner surface of the transparent outer portion (i.e. outer portion 607) of the second support portion of the apparatus. A graph of modelled collection efficiency (%) as a function of slope error in the primary reflector is depicted in FIG. 6B showing a significant increase in the overall collection efficiency when a frustum-shaped secondary reflector is used.

FIGS. 6E and 6F are two examples of methods for mounting a frustum-shaped secondary reflector to the inner portion of the second support portion and showing the contiguous relationship between distal portions 667 of the frustum and the inner surface of the transparent outer portion 607 of the second support portion 605.

FIG. 6G shows a representative flux distribution of incident radiation on the photovoltaic cell for the apparatus, wherein the profiles of the primary and secondary concentration elements have been optimised for maximum capture efficiency of the incoming solar radiation. In alternative arrangements of the (primary) reflectors and/or apparatus disclosed herein, it may be desirable for the solar concentrator to be designed such that the photovoltaic cell is illuminated with an even flux distribution. This can be achieved by defocusing regions of the primary reflector towards the corners of the photovoltaic cell, thus removing the peak from the centre of the cell. This could be advantageous by reducing the maximum heat load at the centre of the cell in favour of a more even heat distribution across the photovoltaic cell. Reducing the heating of the cell may be particularly beneficial if the cell is sensitive to increased heat causing a decrease in electrical conversion. A typical flux density distribution across the photovoltaic cell arising from a defocused primary reflector to provide a relatively even flux density across the cell is depicted in FIG. 6H.

To achieve this distributed flux density across the receiving area of the photovoltaic cell, the profile of the primary reflector about either or both the first and second axes may deviates from a paraboloid. For example, regions of the primary reflector may be defocused towards the corners of the receiving area of the photovoltaic cell, thereby removing the peak flux density away from the centre of the cell towards the edges. This may, of course, cause more raditation reflected from the primary reflectors to be incident on the secondary reflectors, which may cause additional losses, therefore optimisation of the flux density requires consideration of the overall flux distribution compared with the value of total reflected radiation received by the cell. Defocusing of the reflective surface of the primary concentrators may be achieved by controlling the slope of the reflective surface, and a method of generating the paraboloid profile of the reflective surface using its slope may be employed as would be appreciated by the skilled addressee. For example, an equation defining the paraboloid reflective surface may be developed, for instance of the generalised form z=(x²+y²)/4f where z, is the paraboloid surface of the reflector in cartesian coordinates x, y and z, and f is the focal length of the reflector. This generalised form may be converted to equations for slope by taking partial derivatives in the x and y planes. The paraboloid defining the reflective surface of the reflector may then be generated by calculating a single point on the surface, and then subsequently integrating the partial derivatives in a discrete manner to give the position of the other points. Using this method of slope integrating to generate the surface, it is then possible to alter the slope functions and have the surface generated as for a paraboloid but with slight changes, i.e. small alterations may be added and adjusted heuristically to give the desired flux pattern on the photovoltaic cell in any of the arrangements of the reflectors and apparatus disclosed herein.

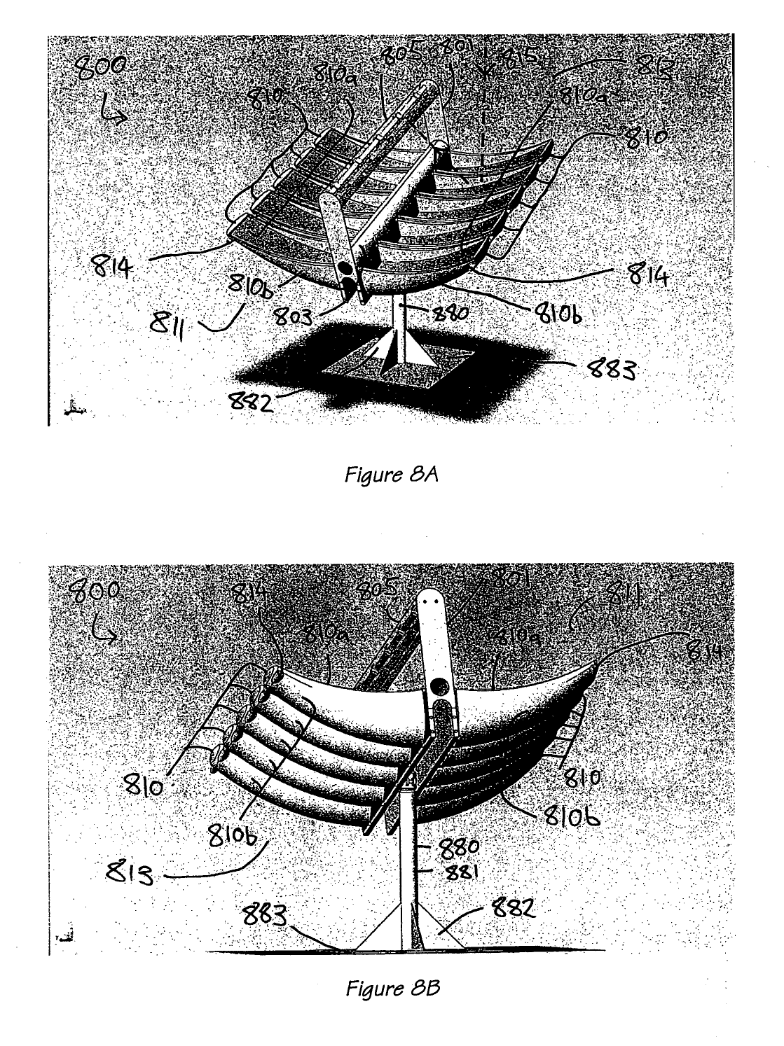

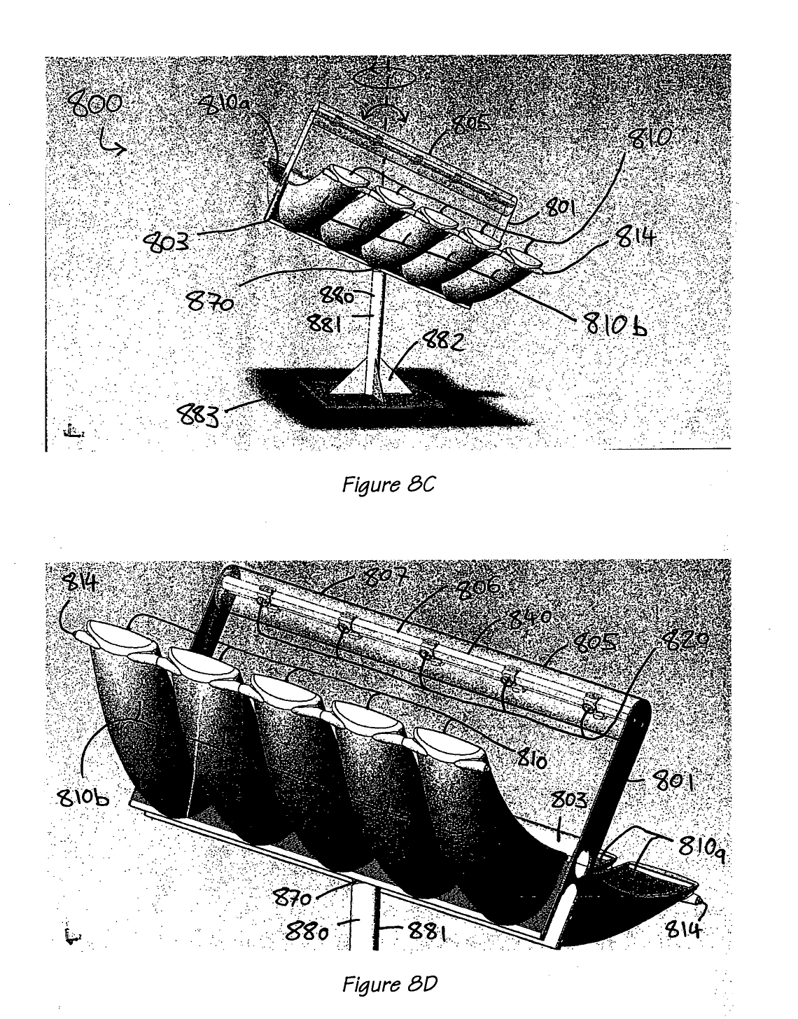

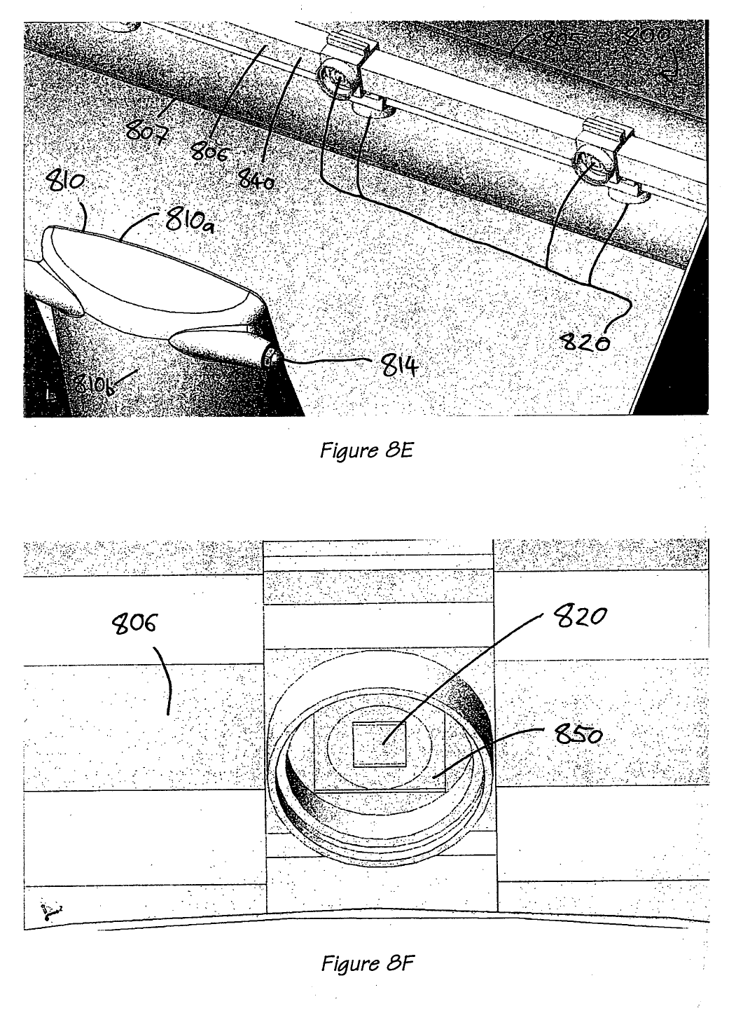

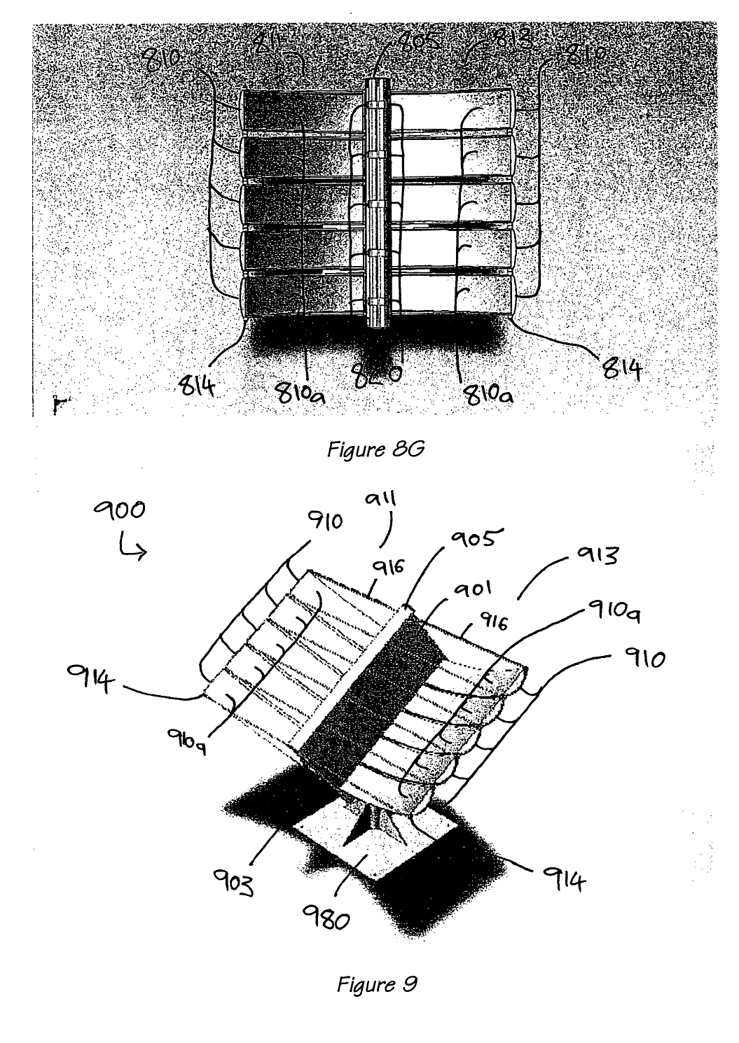

Referring to FIGS. 8A through 8G, FIGS. 8A and 8B are front and rear perspective views, respectively, of an example apparatus 800 for collection and utilisation of solar energy having a support frame 801 comprising first and second elongate support portions 803 and 805, respectively. The first and second elongate support portions are separated and fixedly interconnected by the support frame 801 and are supported by a pivot 870 rotatable in two directions as shown in FIG. 8C by suitable controller and drive motors, operatively coupled to solar tracking means (not shown). The apparatus 800 comprises two arrays 811 and 813 of five primary solar concentrating elements 810 being fixedly attached to opposing sides of the first elongate support portion 803 and ten photovoltaic cells 820 (see FIGS. 8D through 8F) being fixedly attached to and arrayed along the second elongate support portion 805 to maintain a constant optical working relationship between the primary solar concentrating elements 810 and their respective photovoltaic cells 820. The primary solar concentrating elements 810 are elongate solar reflectors having an inner surface 810a and an outer surface 810b, the inner surface 810a being reflective. The reflective inner surface 810a may comprise a reflective film. The reflective film may be removable and replaceable. The primary solar concentrating elements 810 may be configured such that a tie rod 814 may pass through each array (811 and 813) of primary solar concentrating elements 810 to reinforce the apparatus. As depicted in FIG. 8A, the inner surface 810a of the primary solar concentrating elements 810 are adapted to receive incoming solar radiation 815 and direct the solar radiation to their respective photovoltaic cells 820. The photovoltaic cells 820 are adapted to receive the solar radiation 815 which is incident upon the inner surface 810a of the primary solar concentrating elements 810 and convert such radiation 815 to electrical energy.

Referring to FIG. 8B, pedestal mount 880 may comprise a vertical member 881 to which pivot 870 is mounted, a base plate 883 and braces 882 to support the vertical member 881 mounted on base plate 883. FIG. 8C is a side view of the example apparatus depicting the two directions of movement provided by pivot 870 and its controller and drive motors (not shown). Specifically, pivot 870 and its controller and drive motors provides 360° of rotation about the vertical axis of pedestal mount 880 and about 360° of rotation about the horizontal axis of the vertical member 881 of pedestal mount 880 interrupted by the vertical member 881 of pedestal mount 880, which is operatively coupled to solar tracking means (not shown) in order to adjusts the elevation angle and also adjust the horizontal angle of the primary solar concentrating elements 810 to correspond with changes in the sun's position throughout a daylight period.

FIG. 8D is of an alternate side view each demonstrating the arrangement of the primary solar concentrating elements 810 fixedly attached along one side of the first elongate support portion 803. FIGS. 8E and 8F are close-up views demonstrating the arrangement of the photovoltaic cells 820 fixedly attached to and arrayed along the second elongate support portion 805. Referring to FIGS. 8D and 8E, there are shown close-up views of an example arrangement of the second elongate support portion 805 of support frame 801. In this arrangement, second elongate support portion 805 comprises an outer support portion 807 and an inner support portion 806, which inner support portion 806 comprises a heat conversion means 840 for converting excess solar radiation energy incident thereon. Outer support portion 807 is substantially transparent to allow incoming solar radiation 815 to be incident on photovoltaic cells 820. Outer support portion 807 is primarily designed as a protective shield for the photovoltaic cells 820, to protect them and their electrical connections from environmental elements such as wind, rain, or tampering (e.g. damage by animals). Inner support portion 806 is a rigid support member comprising a means (e.g. hollow portion (or duct) 841 of the inner support portion 806—not shown) for flowing a fluid there through (e.g. water). In use, the fluid is flowed through the second elongate support portion 805 and is heated by the heat generated in the photovoltaic cells 820 caused by excess solar radiation incident thereon and therefore to regulate the heat of photovoltaic cells 820. Additional solar radiation may also be incident directly on the inner support portion 806 of second support portion 805 which may also contribute to heating the fluid flowing there through. Heat conversion means 840 may be adapted to provide hot water for domestic or commercial use.

FIG. 8F is a close-up view of one of the photovoltaic cells 820 fixedly attached to the inner support portion 806 of second elongate support portion 805. The photovoltaic cell 820 is surrounded by a secondary solar concentrating element 850 that is in constant optical working engagement with the reflective inner surface 810a of the corresponding primary solar concentrating element 810 and photovoltaic cell 820. The secondary solar concentrating element may reflect radiation incident on and reflected by the inner surface 810a of its corresponding primary solar concentrating element 810 to its corresponding photovoltaic cell 820, thus contributing to the electrical and heat generation of the apparatus 800 and increasing the conversion efficiency.

In summary, example apparatus 800 is designed to provide a simple geometric arrangement for concentrating solar radiation onto photovoltaic cells and converting said radiation to electrical energy with active heat removal that may be adapted to provide hot water for domestic or commercial use.

FIG. 8G is a top view of the example apparatus 800 further demonstrating the relative arrangements of the two arrays 811 and 813 of primary solar concentrating elements 810 fixedly attached along the opposing sides of the first elongate support portion 803 and of the photovoltaic cells 820 fixedly attached to and arrayed along the second elongate support portion 805 to maintain a constant optical working relationship between the elongate solar reflectors of primary solar concentrating elements 810 and their respective photovoltaic cells 820.

Referring to FIG. 9, there is depicted a front perspective view of an alternative example apparatus 900 for collection and utilisation of solar energy having a support frame 901 comprising first and second elongate support portions 903 and 905 respectively. The first and second elongate support portions are separated and fixedly interconnected by support frame 901. The apparatus 900 comprises two arrays 911 and 913 of five primary solar concentrating elements 910 and ten photovoltaic cells 920 (not shown) being fixedly attached to and arrayed along the second elongate support portion 905 to maintain a constant optical working relationship between the primary solar concentrating elements 910 and their respective photovoltaic cells 920. The primary solar concentrating elements 910 are elongate solar reflectors having an inner surface 910a and an outer surface 910b, the inner surface 910a being reflective. The reflective inner surface 910a may comprise a reflective film. The reflective film may be removable and replaceable. The primary solar concentrating elements 910 may be configured such that a tie rod 914 may pass through each array (911 and 913) of primary solar concentrating elements 910 to reinforce the apparatus. The primary solar concentrating elements 910 may also be configured such that a tie bar 914 extending from either side of each of the primary solar concentrating elements 910 is connected to second elongate support portion 905 to further reinforce the apparatus. The primary solar concentrating elements 910 are adapted to receive incoming solar radiation and direct the solar radiation to their respective photovoltaic cells 920. The photovoltaic cells 920 are adapted to receive the solar radiation which is incident upon the inner surface 910a of the primary solar concentrating elements 910 and convert such radiation to electrical energy.

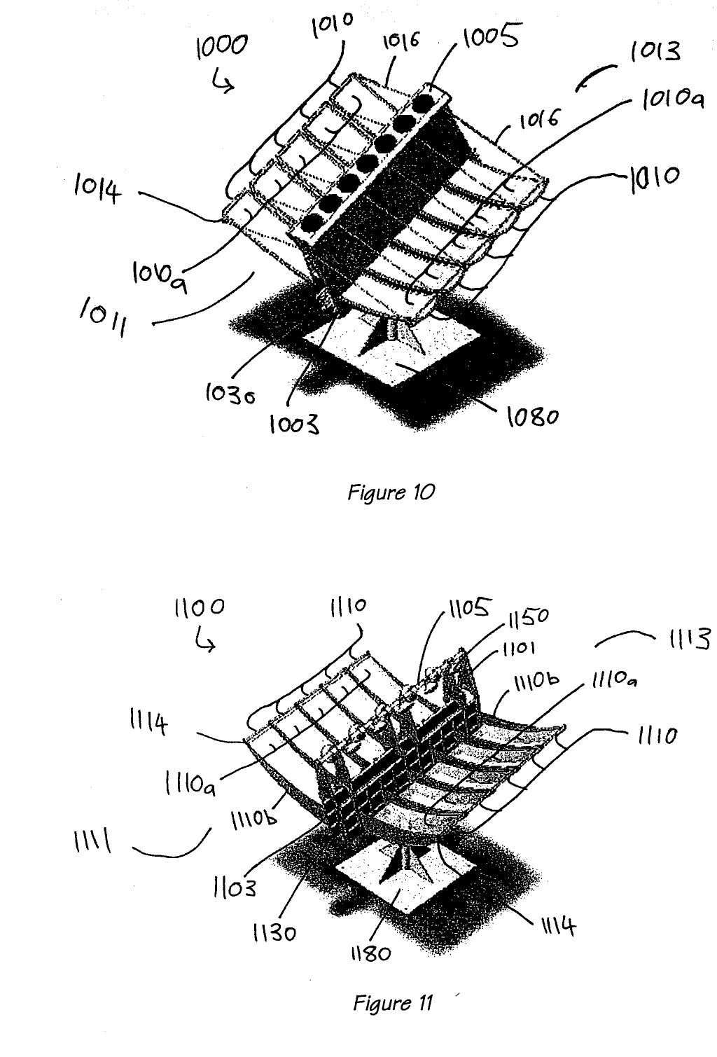

Referring to FIG. 10, there is depicted a front perspective view of another alternative example apparatus 1000 for collection and utilisation of solar energy, having a support frame 1001 comprising first and second support elongate portions 1003 and 1005 respectively. The first and second elongate support portions are separated and fixedly interconnected by support frame 1001. The apparatus 1000 comprises two arrays 1011 and 1013 of five primary solar concentrating elements 1010 and ten photovoltaic cells 1020 (not shown) being fixedly attached to and arrayed along the second elongate support portion 1005 to maintain a constant optical working relationship between the primary solar concentrating elements 1010 and their respective photovoltaic cells 1020. The primary solar concentrating elements 1010 are elongate solar reflectors having an inner surface 1010a and an outer surface 1010b, the inner surface 1010a being reflective. The reflective inner surface 1010a may comprise a reflective film. The reflective film may be removable and replaceable. The primary solar concentrating elements 1010 may be configured such that a tie rod 1014 may pass through each array (1011 and 1013) of primary solar concentrating elements 1010 to reinforce the apparatus. The primary solar concentrating elements 1010 may also be configured such that a tie bar 1014 extending from either side of each of the primary solar concentrating elements 1010 is connected to second elongate support portion 1005 to further reinforce the apparatus. The primary solar concentrating elements 1010 are adapted to receive incoming solar radiation and direct the solar radiation to their respective photovoltaic cells 1020. The photovoltaic cells 1020 are adapted to receive the solar radiation which is incident upon the inner surface 1010a of the primary solar concentrating elements 1010 and convert such radiation to electrical energy.

The second elongate support portion 1005 of apparatus 1000 comprises a heat conversion means (not shown) for converting excess solar radiation energy incident thereon which comprises an inner support portion (not shown). The inner support portion is a rigid support member comprising a means (e.g. a hollow portion) for flowing a fluid there through (e.g. water). In use, the fluid is flowed through the second elongate support portion 1005 and is heated by the heat generated in the photovoltaic cells 1020 caused by excess solar radiation incident thereon and therefore to regulate the heat of photovoltaic cells 1020. The first elongate support portion 1003 of apparatus 1000 further comprises a radiator 1070 to receive the hot fluid exiting the heat conversion means 1040 where excess heat may be dissipated before being returned to the heat conversion means in the second elongate support portion 1005.

Referring to FIG. 11, there is depicted a front perspective view of yet another alternative example apparatus 1100 for collection and utilisation of solar energy, having a support frame 1101 comprising first and second support elongate portions 1103 and 1105 respectively. The first and second elongate support portions are separated and fixedly interconnected by support frame 1101. The apparatus 1100 comprises two arrays 1111 and 1113 of five primary solar concentrating elements 1110 and ten photovoltaic cells 1120 (not shown) being fixedly attached to and arrayed along the second elongate support portion 1105 to maintain a constant optical working relationship between the primary solar concentrating elements 1110 and their respective photovoltaic cells 1120. The primary solar concentrating elements 1110 are elongate solar reflectors having an inner surface 1110a and an outer surface 1110b, the inner surface 1110a being reflective. The reflective inner surface 1110a may comprise a reflective film. The reflective film may be removable and replaceable. The primary solar concentrating elements 1110 may be configured such that a tie rod 1114 may pass through each array (1111 and 1113) of primary solar concentrating elements 1110 to reinforce the apparatus. The primary solar concentrating elements 1110 are adapted to receive incoming solar radiation and direct the solar radiation to their respective photovoltaic cells 1120. The photovoltaic cells 1120 are adapted to receive the solar radiation which is incident upon the inner surface 1110a of primary solar concentrating elements 1110 and convert such radiation to electrical energy.

The second elongate support portion 1105 of apparatus 1100 comprises a heat conversion means (not shown) for converting excess solar radiation energy incident thereon which comprises an inner support portion (not shown). The inner support portion is a rigid support member comprising a means (e.g. hollow portion) for flowing a fluid there through (e.g. water). In use, the fluid is flowed through the second elongate support portion 1105 and is heated by the heat generated in the photovoltaic cells 1120 caused by excess solar radiation incident thereon and therefore to regulate the heat of photovoltaic cells 1120. The first elongate support portion 1103 of apparatus 1100 further comprises a radiator 1130 where to receive the hot fluid exiting the heat conversion means 1140 where excess heat is dissipated before being returned to the heat conversion means in the second elongate support portion 1105.

Further, each photovoltaic cell 1120 is surrounded by a secondary solar concentrating element 1150 that is in constant optical working engagement with the corresponding primary solar concentrating element 1110 and photovoltaic cell 1120. The secondary solar concentrating element may reflect radiation incident thereon and reflected by its corresponding primary solar concentrating element 1110 to its corresponding photovoltaic cell 1120, thus contributing to the electrical and heat generation of the apparatus 1100 and increasing the conversion efficiency.

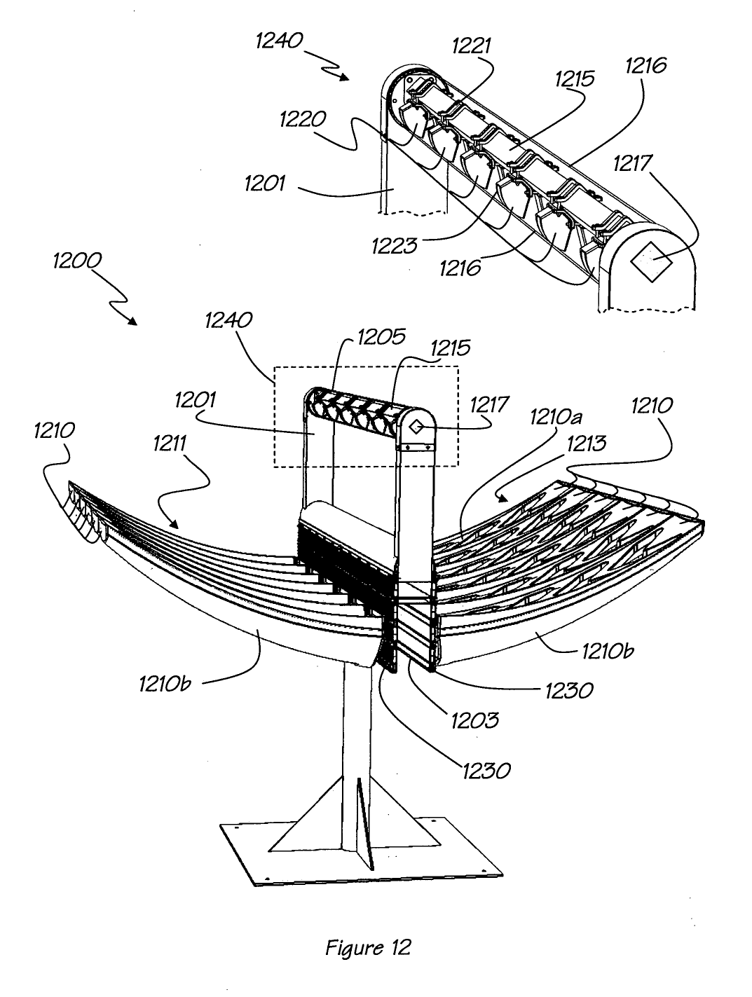

FIG. 12 is a front perspective view of another alternative example apparatus for collection and utilisation of solar energy with detail showing frustum-shaped secondary reflector. Referring to FIG. 12, there is depicted a front perspective view of yet another alternative example apparatus 1200 for collection and utilisation of solar energy, having a support frame 1201 comprising first and second support elongate portions 1203 and 1205 respectively. The first and second elongate support portions are separated and fixedly interconnected by support frame 1201. The apparatus 1200 comprises two arrays 1211 and 1213 of six primary solar concentrating elements 1210 and twelve photovoltaic cells (not shown) being fixedly attached to and arrayed along the second elongate support portion 1205 to maintain a constant optical working relationship between the primary solar concentrating elements 1210 and their respective photovoltaic cells. The primary solar concentrating elements 1210 are elongate solar reflectors having an inner surface 1210a and an outer surface 1210b, the inner surface 1210a being adapted to support a reflector (not shown), which may comprise a reflective film. The inner surface 1210a may be concave, and wherein the surface curves about a first axis and a second axis, the second axis being in a plane generally normal to the first axis and curved about the first axis as depicted in FIG. 2D, such that a reflector when fitted to the inner surface 1210a (e.g. reflective film) is provides a concave reflective surface which also curves about the first axis and the second axis. The reflective film may be removable and replaceable. The primary solar concentrating elements 1210 are adapted to receive incoming solar radiation and direct the solar radiation to their respective photovoltaic cells. The photovoltaic cells are adapted to receive the solar radiation which is incident upon the inner surface 1210a of primary solar concentrating elements 1210, when fitted with a suitable reflector, and convert such radiation to electrical and/or thermal energy.

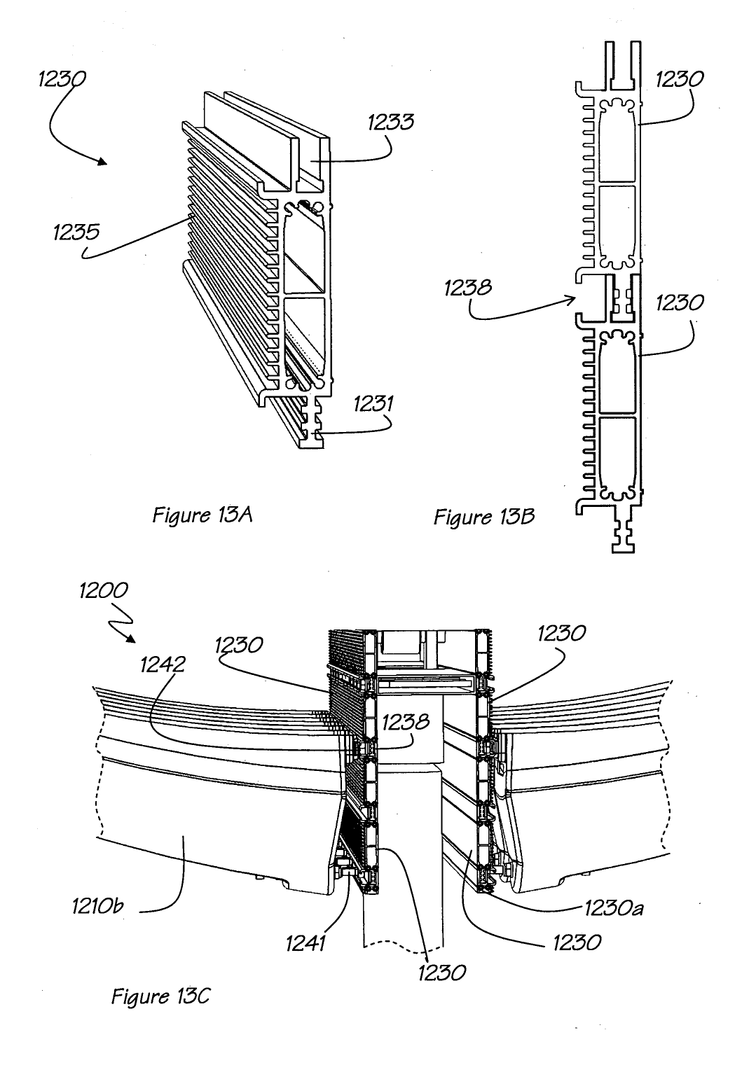

The second elongate support portion 1205 of apparatus 1200 comprises a heat conversion means (not shown) for converting excess solar radiation energy incident thereon which comprises an inner support portion 1215. The inner support portion 1215 is a rigid support member comprising a means (e.g. hollow portion) for flowing a fluid there through (e.g. water) and comprises a fluid inlet 1217 and a fluid outlet (not shown). In use, the fluid is flowed through the second elongate support portion 1205 and is heated by the heat generated in the photovoltaic cells caused by excess solar radiation incident thereon and therefore to regulate the heat of photovoltaic cells. The first elongate support portion 1203 of apparatus 1200 is comprised of modular support portions 1230, for example as shown in FIGS. 13A to 13C. Such modular support portion may assist is the ease of adjustment in the optical alignment of the primary solar concentrating elements 1210 with a respective photovoltaic cell, which may be particularly advantageous during prototype stages of development.

Detail 1240 shows the second support portion 1205 which comprises inner support portion 1215 and transparent outer support portion 1216. In the present arrangement, the second support portion 1205 comprises a plurality of secondary frustum-shaped imaging elements 1220 for example, secondary reflectors 660 as shown in FIG. 6A. Secondary imaging elements 1220 are attached to inner portion 1215 of the second support portion 1205 and enclose a respective photovoltaic cell (not shown) such that the rear surface of the photovoltaic sell is abutted against inner portion 1215 to be in thermal engagement therewith. Mounting brackets 1221 are used to secure the secondary imaging elements 1220 to the inner portion 1215. In the present arrangement the frustum-shaped secondary imaging elements 1220 are adapted such that the distal portions 1223 thereof are configured to be contiguous with the inner surface of the transparent outer portion 1216 of second support portion 1205.

FIG. 13A is a perspective view of an example modular extrusion 1230 for use in the first support frame of the apparatus. Extrusion 1230 is hollow to keep the weight of the apparatus to a minimum where possible, and comprises strengthening ribs 1235. Extrusion 1230 further comprises a male portion 1231 and a female portion 1233 such that in use, male portion 1231 is engaged with female portion 1233 as shown in FIG. 13B. Extrusion 1230 further comprises portions 1236 and 1237 configured such that, when engaged with a like extrusion as shown in FIG. 13B, portions 1236 and 1237 for a receptacle 1238. In use, as shown in FIG. 13C with reference to apparatus 1200 of FIG. 12, a plurality of extrusions 1230 are connected together to form the first support portion 1203 of apparatus 1200. Primary solar concentrating elements 1210 comprise mounting features 1241 and 1242 which are engaged with receptacles 1238 for mounting the primary concentrating elements 1210 to the first support portion 1203. A further extrusion 1230a comprising a suitable female portion and receptacle portion, may also be provided to engage the lowermost extrusion 1230 forming the first support portion 1205 to provide a suitable receptacle 1238 for mounting the primary concentrating elements 1210 as required.

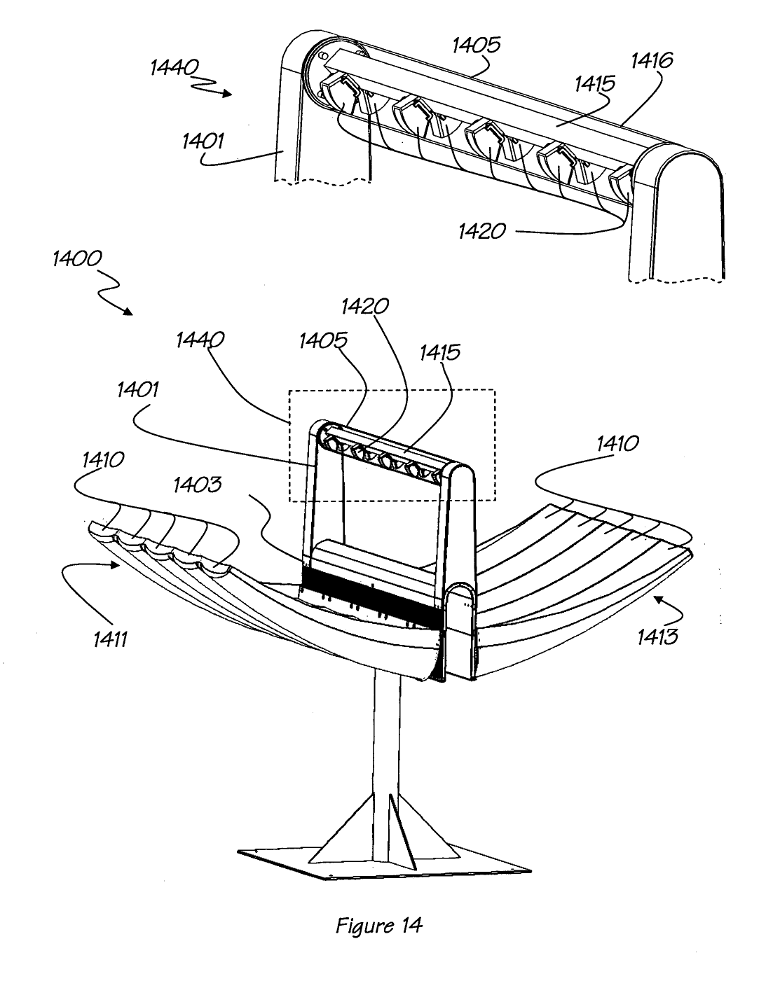

FIG. 14 is a front perspective view of another alternative example apparatus 1400 for collection and utilisation of solar energy similar to that of apparatus 1200 of FIG. 12. Apparatus 1400 comprises a support frame 1401 comprising first and second support elongate portions 1403 and 1405 respectively. The first and second elongate support portions are separated and fixedly interconnected by support frame 1401. The apparatus 1400 comprises two arrays 1411 and 1413 of five primary solar concentrating elements 1410. In this arrangement, the primary concentrating elements 1410 are each joined together as a continuous sheet. This is likely to have advantage in reducing manufacturing costs compared to the segmented arrangements depicted in FIGS. 8 to 12.

Apparatus 1400 further comprises ten photovoltaic cells (not shown) fixedly attached to and arrayed along the second elongate support portion 1405 to maintain a constant optical working relationship between the primary solar concentrating elements 1410 and their respective photovoltaic cells. Detail 1440 shows a plurality of frustum-shaped secondary reflectors 1420 (similar to those described with reference to FIGS. 6C, 6D and 12) mounted to inner portion 1415 of the second support portion 1205.

Referring to FIG. 15, there is depicted a flow diagram of a system for collection and utilisation of solar energy in accordance with the present invention described herein. In use, the primary solar concentrating element 1510 of apparatus 1500 is adapted to receive incoming solar radiation 1515 incident thereon and to direct the solar radiation to photovoltaic cell 1520 such that they maintain a constant optical working relationship. Secondary solar concentrating element 1550 is also in constant optical working engagement with primary solar concentrating element 1510 and photovoltaic cell 1520 such that it is adapted to direct solar radiation incident thereon from primary solar concentrating element 1510 to photovoltaic cell 1520, thus contributing to the electrical and heat generation of the apparatus 1500 and increasing the conversion efficiency. The photovoltaic cell 1520 is adapted to receive the solar radiation which is incident upon primary and secondary solar concentrating elements 1510 and 1550 and to convert such radiation to electrical energy. The photovoltaic cell 1520 may be a CPV cell.

The electrical energy generated in photovoltaic cell 1520 is operatively coupled (e.g. via wires) to a suitable low voltage inverter 1521 to convert the direct current electrical power generated in photovoltaic cell 1520 to alternating current electrical power. The alternating current electrical power may be measured in meter 1522 before being passed to domestic or commercial use 1523.

The second support portion 1506 comprises a heat conversion means 1540 for converting excess solar radiation energy incident thereon to heat energy. The photovoltaic cell 1520 is in thermal communication with the inner support portion 1506 for transferring excess solar radiation incident on the photovoltaic cell 1520 to the heat conversion means 1540 by conductive heat transfer and therefore regulate the heat of photovoltaic cell 1520 (photovoltaic cells are typically less efficient at elevated temperatures). The heat conversion means 1540 comprises a pump 1590 for flowing a fluid (e.g. water) through hollow portion 1541, wherein in use said fluid is heated by excess solar radiation incident on the inner support portion 1506 and excess solar radiation incident on the photovoltaic cell 1520. At least part of the fluid from the heat conversion means 1540 may be flowed to storage tank 1598 which comprises fluid inlet 1596 for topping up the fluid level, and fluid outlet 1597 for removing fluid, particularly hot fluid. Where the hot fluid removed from outlet 1597 is hot water, this may be suitable for domestic or commercial use 1599. Alternatively, where a fluid other than water is used, a heat exchanger (not shown) may be placed after outlet 1597 in order to provide hot water for domestic or commercial use. At least part of the fluid from the heat conversion means 1540 or from storage tank 1598 may be flowed to radiator 1530 where excess heat is dissipated before being returned to the hollow portion 1541 of heat conversion means 1540 by pump 1590. The flow rate of pump 1590 is variable and operated by flow control means 1591 which includes a temperature sensor (e.g. a thermocouple) operatively disposed to measure the temperature of circulating fluid. The pump speed and thereby the flow rate of fluid through the hollow portion 1541 of the heat conversion means 1540 may be dictated by the temperature of the circulating fluid measured and resultantly the temperature of the fluid exiting the heat conversion means 1540.

Further, apparatus 1500 is supported by pivot 1570 which is rotatable in two directions by suitable controller and drive motors 1571 and 1572, respectively, operatively coupled (eg via wires or wirelessly) to solar tracking means 1573 to adjust the elevation angle and horizontal angle of the primary solar concentrating elements 1510 to correspond with changes in the sun's position throughout a daylight period. Approximately 30% more power (kWhrs) is expected to be generated with the use of solar tracking means compared for the same peak kW rating of current systems since photovoltaic cells are operating at close to peak power for longer during each day.

In the system for collection and utilisation of solar energy depicted in the flow diagram of FIG. 15 it is to be understood that the apparatus 1500 may be substituted by any one of the example apparatus 800, 900, 1000, 1100, 1200 and 1400 depicted in FIGS. 8A through 8G, 9, 10, 11, 12 and 14, respectively, or any other suitable apparatus for collection and utilisation of solar energy herein described with appropriate modifications.

In particular arrangements, the solar collector described herein is adapted to move with the sun, that is, to face toward the sun as the sun changes its position during a daylight period. The elevation angle of the sun changes as the sun ascends and descends, and the horizontal angle of the sun changes with the apparent movement of the sun from horizon to horizon. A solar tracking system therefore adjusts an elevation angle of the solar collector and also adjusts a horizontal angle of the solar collector to correspond with changes in the sun's position throughout a daylight period. Most high concentration factor (>50 suns) solar collectors require a dual axis tracking system with a precision greater than flat panel PV tracking systems, and most existing concentrator devices have custom tracking systems particularly adapted for the size of each individual device.

Therefore, in any one of the arrangements of the solar collector apparatus's described herein, the support frame of the apparatus may be adapted to track the apparent sun's motion across the sky to optimise the solar collection efficiency. Such a tracking system may be envisaged by supporting the apparatus one at least one pivot (not shown) which may be rotatable in at least two directions. The apparatus may then further comprise solar tracking means for moving the support frame about the pivot to adjust an elevation angle of the apparatus and a horizontal angle of the apparatus with respect to changes in the direction of incident solar radiation over a daylight period, thereby to track the apparent sun's motion across the sky. Such tracking system may comprise a dual-axis telescope mount with suitable controller and drive motors, together with a high precision (<0.1°) solar tracking control system.

The apparatus' depicted herein are envisaged to provide significantly lower cost ($/watt) than flat panel photovoltaic modules for prototype components. Components designed and manufactured for the present apparatus (mirror, heat tubes, tracker & inverter) are likely to be less than half the cost of flat panel per kW equivalent. The apparatus is also able to be mass-manufactured using many existing component manufacturers rather than requiring significant R&D to build a manufacturing plant (e.g. thin film and organic dye PV).

Thus the highest overall system energy efficiency may be achieved by combining highest efficiency photovoltaic cells with additional hot water utilisation. High efficiency also reduces the size of the installation for the same power output compared to flat panel photovoltaic and thin film photovoltaic. Also, since the present apparatus are adapted to be used with a solar tracking system, approximately 30% more power (kWhrs) is expected to be generated compared for the same peak kW rating of current systems since photovoltaic cells are operating at close to peak power for longer during each day. Furthermore, existing high concentrating photovoltaic systems do not utilise the heat generated, but rather such heat is treated as waste.

An apparatus of the invention utilises commercially available III-V triple junction CPV cells with an efficiency of about 39% today and projected to reach ˜45% in 5 years. A system of the invention may comprise an apparatus of the invention operatively coupled to a solar tracking system. The apparatus of the invention may comprise means for 2-axis tracking of the sun by the primary reflectors or primary solar concentrating elements. The solar tracking system may be operatively coupled (e.g. via wires or wirelessly) to the means for 2-axis tracking of the sun by the primary reflectors or the primary solar concentrating elements. The photovoltaic cell is a triple junction concentrating photovoltaic cell (CPV cell). The solar tracking system may be operatively coupled (e.g. via wires or wirelessly) to the means for 2-axis tracking of the sun by the primary reflectors or the primary solar concentrating elements whereby their position is adjusted so that they track the movement of the sun. The CPV cells of the apparatus of the invention may be operatively coupled (e.g. via wires) to a direct current to alternating current converter to convert the direct current electrical power generated by the CPV cells to alternating current electrical power suitable for domestic or commercial use. The inverter may be coupled to a meter to measure the amount of electrical power generated by the CPV cells.

The apparatus of the invention is designed to combine the necessary CPV heat removal with productive use of the low-grade heat as hot water. A solar reflector in the apparatus of the invention may comprise geometry that concentrates light to a point required for the (10×10) mm CPV cell. A parabolic dish reflector is the simple geometric form required to focus light to a point. The basic design of a solar reflector used in an apparatus of the invention is to take a parabolic dish form and remove a rectangular segment. The inside of the segment may be then coated or lined with a reflective film. A suitable reflective film may comprise an Al sheet MIRO-SUN 90 weatherproof, 0.3 mm thick. This off axis dish segment (solar reflector) is then repeated down both sides of central support frame and receiver tube. The CPV cells are mounted along the length of the apparatus near the focal point or area of each solar reflector r segments to be positioned to receive radiation reflected from the reflectors. Heat is conducted away from the CPV cell by a circulating heat transfer fluid such as water in conductive thermal communication with the cell. A system comprising the apparatus of the invention may include a temperature sensor (e.g. a thermocouple) operatively disposed in the system to measure the temperature of circulating heat transfer fluid. The temperature sensor may be coupled to a pump controller which in turn may be linked to a pump which is operatively coupled with the apparatus of the invention to pump the heat transfer fluid through the receiver tube. The pump controller may be adapted to control the speed of the pump as a function of the temperature of the heat transfer fluid. This may be done by controlling the pump speed and thereby the flow rate of heat transfer fluid through the receiver tube and resultantly the temperature of the heat transfer fluid exiting the receiver tube. Temperature increase along the receiver tube may be controlled by a thermostatically adjusted circulating pump which is adapted to pump the heat transfer fluid through the receiver tube at a variable flow rate. Thus where the heat transfer fluid is water the flow rate of water through the tube may be controlled so that 65 degree Celsius hot water is piped via tubing from the outlet of the receiver tube to an inlet of a conventional hot water storage tank and from the outlet of the hot water storage tank via tubing back to the inlet of the receiver tube. The tubing to the hot water storage tank may be insulated and return flow may be through a high surface area passive radiator tube. The support frame for the primary reflectors or primary solar concentrating elements may double as an additional heat radiator with internal cavities and high surface area.

The apparatus of the invention has two key advantages over other CPV solar collector designs. It has active heat conduction away from the CPV cell allowing higher concentration factors (current design about 1450 suns) which simply equates to near linear power output increase with concentration factor. The second significant advantage is that the optical classification of a solar reflector with a secondary reflector or refractor (XR) has approximately double the angular tracking error tolerance compared to first generation Fresnel lens systems. The single best measure of likely success is the $/watt of installed PV & CPV systems. Commercially available CPV cells (39%) are increasing efficiency following continual laboratory world record CPV efficiencies (41.6% SpectroLab mono, 43% UNSW split). Unlike PV manufacturers who must modify their production lines to manufacture a new solar cell and module, CPV solar collectors can substitute the new higher efficiency CPV cells into the collector, with the same form factor. Significant distinctions exist amongst the Concentrating Photovoltaic (CPV) technologies with division between systems based on low concentration factor 2-100 suns, which are typically Si CPV, and high concentration factor HCPV (500-2,000 suns) triple junction cells. Whilst both approaches are technically valid they have different cost structures, different manufacture & supply requirements and different system performance.

There may also be a gap between the primary reflector(s) or primary solar concentrating element(s) and the first support portion to allow drainage of any rain and dust. There may also be a narrow gutter running longitudinally along the elongate solar reflectors to allow drainage of any rain and dust. The daily cycle will tip the collector over allowing any leaves or light debris that might collect to blow away. One expects not to site the collector under or adjacent to trees. Between each primary reflector or primary solar concentrating element there may be a small gap to allow wind to pass more easily over and through the collector, thereby reducing the structural wind loading requirement. The same is true for the gap between the primary reflector(s) or primary solar concentrating element(s) and the first support portion, whereby passing wind is directed to the gap and increases the radiative cooling effect of the support frame.

The solar collector reflective surfaces are designed for easy cleaning with, for example, a windscreen wiper blade. If after years of use grime is an issue, the Al mirror film, for example, is low cost and replaceable by simply peeling off the old and adhering the replacement mirror in place. The tracker will manually drive the solar collector “off sun” for cleaning.

The reflective surfaces will not heat significantly to form a hazard. The secondary reflector or refractor also will not heat up significantly. The hottest element is the CPV cell which may be sealed behind the glass receiver tube and therefore be inaccessible for potential burns. The hot water must be kept below scalding temperature (which is part of the existing mandatory temp limiting valve requirements) so should be safe for a casual touch.

Two or more apparatus of the invention may be connected (electrically for the solar cells and hydraulically for the heat transfer fluid) in series and/or parallel.

It will be appreciated that the methods, apparatus, devices, and systems described/illustrated above at least substantially provide a solar collection and utilisation apparatus which is particularly suited for domestic or small commercial applications and is readily adapted to be installed on residential premises.

The apparatus described herein, and/or shown in the drawings, are presented by way of example only and are not limiting as to the scope of the invention. Unless otherwise specifically stated, individual aspects and components of the apparatus may be modified, or may have been substituted therefore known equivalents, or as yet unknown substitutes such as may be developed in the future or such as may be found to be acceptable substitutes in the future. The apparatus may also be modified for a variety of applications while remaining within the scope and spirit of the claimed invention, since the range of potential applications is great, and since it is intended that the present apparatus be adaptable to many such variations.

1. An apparatus for collecting solar energy, the apparatus including:
a support frame; and
a plurality of reflectors mounted on the frame in an array to reflect solar radiation and so as to provide a first axis, each reflector having a reflector surface, each surface being concave, and wherein the surface curves about the first axis, with each surface being curved about a second axis, and wherein each second axis is located in a plane generally normal to the first axis and curved about the first axis.

2. The apparatus as claimed in claim 1, wherein each reflector is elongated so that said second axis is a longitudinal axis with said surface in transverse cross-section having a parabolic configuration.

3. The apparatus as claimed in claim 2, wherein said second axis follows a parabolic path.

4. The apparatus as claimed in claim 1, wherein each reflector is elongated so that said second axis is a longitudinal axis, with said surface in transverse cross-section an elliptical configuration, a hyperbolic configuration or a configuration that is a segment of a circle.

5. The apparatus as claimed in claim 1, wherein each reflector surface about either or both the first and second axes thereof deviates from a paraboloid such that the radiation reflected therefrom irradiates an area with a substantially uniform flux density.

6. The apparatus of claim 1, wherein:
there is at least one photovoltaic cell associated with each surface and positioned relative to the associated surface so as to receive radiation reflected by the associated surface and to convert the received radiation to electrical energy.

7. The apparatus of claim 6, wherein each surface is configured and is positioned relative its associated said cell so that radiation reflected from each surface irradiates a receiving area of the cell with a substantially uniform flux density.

8. The apparatus as claimed claim 6, wherein:
each reflector comprising a concave reflector surface; and
a plurality of photovoltaic cells, each photovoltaic cell being disposed to receive radiation incident on and reflected by the reflector surface of the corresponding reflector.

9. The apparatus as claimed in claim 8, wherein the plurality of primary reflectors comprises a continuous reflective sheet having a plurality of concave reflective surfaces in operative engagement with a respective photovoltaic cell, and an associated one of the primary reflectors, with each secondary reflector reflecting received solar radiation at the associated primary reflector.

10. The apparatus as claimed in claim 9, wherein the at least one secondary solar reflector is a frustum-shaped reflector.

11. The apparatus as claimed in claim 5, further comprising heat conversion means for converting excess solar radiation energy incident thereon to heat energy, wherein the at least one photovoltaic cell is in thermal communication with the heat conversion means for transferring excess solar radiation incident on the at least one photovoltaic cell to the heat conversion means by conductive heat transfer.

12. The apparatus as claimed in claim 11, wherein the heat conversion means comprises a means for flowing a fluid therethrough, wherein said fluid is heated by excess solar radiation incident on the second support portion.

13. The apparatus as claimed in claim 12, wherein the heat conversion means comprises a hollow portion and a pump for flowing a fluid through the hollow portion.

14. The apparatus as claimed in claim 6, wherein the support frame is supported by at least one pivot rotatable in at least two directions and the apparatus further comprises solar tracking means for moving the support frame about the pivot to adjust an elevation angle of the apparatus and a horizontal angle of the apparatus with respect to changes in the direction of incident solar radiation over a daylight period, thereby to track the sun's motion across the sky and incident solar radiation incident on the at least one primary reflector to the photovoltaic cell.

15. The apparatus as claimed in claim 6, further comprising an electrical conversion means operatively coupled with the photovoltaic cell for conversion of direct current electrical power generated in the photo voltaic cell to alternating current electrical power.
